(19) United States
(12) Patent Application Publication
(10) Pub. No.: US 2013/0329394 A1
(43) Pub. Date: Dec. 12, 2013

(54) PORTABLE ELECTRONIC DEVICE

(71) Applicants: Keisuke Nonaka, Daito-shi (JP); Akito Iwai, Daito-shi (JP); Kenjiro Okamoto, Daito-shi (JP); Toshifumi Yakushinji, Daito-shi (JP); Atsushi Okamoto, Mino-shi (JP); Kenjiro Fujii, Daito-shi (JP); Kazuhito Fukumasu, Daito-shi (JP); Kengo Suzuki, Daito-shi (JP)

(72) Inventors: Keisuke Nonaka, Daito-shi (JP); Akito Iwai, Daito-shi (JP); Kenjiro Okamoto, Daito-shi (JP); Toshifumi Yakushinji, Daito-shi (JP); Atsushi Okamoto, Mino-shi (JP); Kenjiro Fujii, Daito-shi (JP); Kazuhito Fukumasu, Daito-shi (JP); Kengo Suzuki, Daito-shi (JP)

(73) Assignee: KYOCERA CORPORATION, Kyoto (JP)

(21) Appl. No.: 13/576,930

(22) PCT Filed: Feb. 2, 2012
(86) PCT No.: PCT/JP2012/052354

§ 371 Date: Aug. 2, 2012

(30) Foreign Application Priority Data
Feb. 7, 2011 (JP) 2011-023914
Feb. 7, 2011 (JP) 2011-023915
Feb. 7, 2011 (JP) 2011-023916

(51) Int. Cl. H05K 7/14

(52) U.S. Cl. CPC H05K 7/14
USPC 361/807; 361/679.01

(57) ABSTRACT

In a portable electronic device that has a first casing 1 and a second casing 2 coupled to each other via a coupling member and can be selectively set in a closed state and an open state, at an opposing portion between the coupling member and the second casing 2, there are formed a receiving surface 33 and a slide surface 29 that are to be in a slide contact with each other in a first half of a process where both the casings shift from a most separated state to a closest state in the open state, and at an opposing portion between the first casing 1 and the second casing 2, there are formed a projecting portion 10 and a recessed portion 20 that are to be engaged with each other and disengaged from each other in a latter half of the process.

### TECHNICAL FIELD

The present invention relates to a portable electronic device configured by a pair of casings coupled to each other.

### BACKGROUND ART

Conventionally, there has been known a portable electronic device which is configured by coupling a pair of casings to each other and has a display surface arranged on each surface of the casings and which can provide a large amount of pieces of information to a user by both the display surfaces.

Such a portable electronic device has the pair of casings coupled to each other by a linkage member at respective side portions, for example, and based on a turn operation of the linkage member, allows both the casings to be relatively moved between a single-surface exposed state (a closed state) where the pair of casings are overlaid on each other, a display surface (a first display surface) of a lower casing is covered with an upper casing (a second casing), and only a display surface (a second display surface) of the second casing is exposed, and a both-surface exposed state (an open state) where the second casing is moved to the first casing, and the display surfaces of both the casings are exposed on the same plane.

According to such a portable electronic device, because the first display surface and the second display surface are aligned on the same plane in the open state, an image can be displayed by a large screen by using the two display surfaces as one large screen.

Meanwhile, there is proposed a portable electronic device that has a pair of casings coupled to each other via a linkage mechanism, the portable electronic device having a keyboard arranged on a surface of a first casing, and a display arranged on a surface of a second casing. The portable electronic device can be set in a closed state where the surface of the first casing is covered with a back surface of the second casing and only the surface of the second casing is exposed, and a tilt state where the surface of the second casing is inclined with respect to the surface of the first casing at an open angle equal to or larger than 90 degrees and smaller than 180 degrees and the surfaces of both the casings are exposed.

In a portable electronic device that has a first casing and a second casing coupled to each other via a coupling member and can be selectively set in at least two states which include a closed state where a display surface of the first casing is covered with a back surface of the second casing and a display surface of the second casing is closed and an open state where the display surfaces of both the casings are exposed on the same plane, an interval between the two display surfaces can be shortened by employing a configuration in which the second casing is pulled to a first casing side in the open state and by bringing the display surface of the first casing and the display surface of the second casing close to each other on the same plane. Therefore, when an image is displayed by using the two display surfaces as one screen in the open state, a large discontinuity in an image displayed on both the display surfaces is eliminated.

However, in the above portable electronic device, the second casing is turnably supported at a front end portion of the coupling member. Therefore, when a configuration in which the second casing can be displaced to a first casing side in the open state is simply employed, there is a problem in that not only a posture of the second casing becomes unstable because of a turn of the second casing in a process of pulling the second casing to the first casing side in the open state but also the posture of the second casing cannot be held constant in a state where the second casing is finally closest to the first casing.

Further, according to a portable electronic device that has a first casing and a second casing coupled to each other and can be selectively set in three states which include a closed state where a surface of the first casing is covered with a back surface of the second casing and a surface of the second casing is exposed, a tilt state where the surface of the second casing is inclined with respect to the surface of the first casing at an open angle equal to or larger than 90 degrees and smaller than 180 degrees and the surfaces of both the casings are exposed, and an open state where the surfaces of both the casings are exposed on the same plane, an interval between the two display surfaces can be shortened by employing a configuration in which the second casing is pulled to a first casing side in the open state and by bringing the display surface of the first casing and the display surface of the second casing close to each other on the same plane. Therefore, when an image is displayed by using the two display surfaces as one screen in the open state, a large discontinuity in an image displayed on both the display surfaces is eliminated.

However, the above portable electronic device has a configuration in which the first casing and the second casing are brought close to each other and separated from each other in the open state. Therefore, to shift to the tilt state from the state where the second casing is pulled to the first casing side, first, the second casing needs to be separated from the first casing in the open state, and thereafter, the tilt state needs to be set by opening the second casing. Consequently, there is a problem in that two step operations become necessary, and this is complex.

Further, in an electronic device that has a display surface formed on a casing surface by installing a thin display such as a liquid crystal display on a flat casing, there is employed a configuration in which an accommodation chamber for incorporating the display is formed in the casing and the display is accommodated in the accommodation chamber.

In this case, formation of a gap due to an error cannot be avoided between an internal peripheral wall of the accommodation chamber and an external peripheral wall of the display. Therefore, the display can slightly move in the accommodation chamber. However, in an assembled state where a glass plate or the like is set by covering a surface of the display, for example, the display is fixed to a constant position in the accommodation chamber, and the position is not easily deviated.

However, in a portable electronic device that can be selectively set in at least two states which include a closed state where a surface of a first casing is covered with a back surface of a second casing and a surface of the second casing is exposed and an open state where the surfaces of both the casings are exposed on the same plane, when display surfaces are formed by installing thin displays in both the casings, and when a display of at least one of the casings is fixed to a position deviated to a direction to which the display is separated from the other casing due to a gap between an internal peripheral wall of an accommodation chamber and an external peripheral wall of the display formed in the casing as described above, an interval between the two displays arranged in both the casings becomes large corresponding to the deviation, and a large gap is formed between the two display surfaces in the open state.

As a result, there is a problem in that when one continuous image is displayed across the two display surfaces, the image is greatly discontinued by the gap.

An object of the present invention is to provide a portable electronic device that can solve the above problem and can be easily handled.

### SUMMARY OF THE INVENTION

A first portable electronic device according to the present invention has a first casing and a second casing coupled to each other via a coupling member, and can be selectively set in at least two states which include a closed state where a surface of the first casing is covered with a back surface of the second casing and a surface of the second casing is exposed, and an open state where the second casing moves from the closed state by a turn operation of the coupling member and display surfaces of both the casings are exposed on the same plane.

A supporting mechanism that turnably and slidably supports the second casing relative to a front end portion of the coupling member is interposed between the front end portion of the coupling member and the second casing, and the first casing and the second casing can be brought close to each other and separated from each other in the open state.

At an opposing portion between the coupling member and the second casing, there are formed a receiving surface and a slide surface that are to be in slide contact with each other in a first half of a process in which both the casings shift from a most separated state to a closest state in the open state, and at an opposing portion between the first casing and the second casing, there are formed a projecting portion and a recessed portion that are to be detachably engaged with each other in a latter half of the process.

A second portable electronic device according to the present invention has a first casing and a second casing coupled to each other via a coupling member, and can be selectively set in three states which include a closed state where a surface of the first casing is covered with a back surface of the second casing and a surface of the second casing is exposed, a tilt state where the surface of the second casing is inclined with respect to the surface of the first casing at an open angle equal to or larger than 90 degrees and smaller than 180 degrees and the surfaces of both the casings are exposed, and an open state where the surfaces of both the casings are exposed on the same plane.

A supporting mechanism that turnably and slidably supports the second casing relative to a front end portion of the coupling member is interposed between the front end portion of the coupling member and the second casing, and the first casing and the second casing can be brought close to each other and separated from each other in the open state.

The first casing and the second casing have end surfaces that face each other in the open state, the projecting portion is provided on an end surface of one of the casings and the recessed portion is provided on an end surface of the other casing, and the projecting portion and the recessed portion are engaged with and disengaged from each other when the first casing and the second casing are brought close to each other and separated from each other in the open state.

On the projecting portion and the recessed portion, there are formed an engaging surface and an engagement receiving surface that constrain a relative movement of both the casings in a direction orthogonal to a direction of being brought close to each other and separated from each other in a mutually engaged state, and allow displacement of turning the second casing to an inclined posture in the tilt state while separating both the casings from each other

A third portable electronic device according to the present invention has a first casing and a second casing coupled to each other, a display arranged in each of the casings, and a display surface formed to be exposed on a surface of each of the casings, the third portable electronic device can be selectively set in at least two states which include a closed state where a display surface of the first casing is covered with a back surface of the second casing and a display surface of the second casing is exposed, and an open state where the display surfaces of both the casings are exposed on the same plane.

In this case, an accommodation chamber for accommodating a display is formed in at least one of the casings, and between an internal peripheral wall of the accommodation chamber and an external peripheral wall of the display accommodated in the accommodation chamber, there is arranged a pressing mechanism that presses the display to the other casing side in the open state.

### BRIEF DESCRIPTION OF THE DRAWINGS

FIG. 1 is a perspective view illustrating a closed state of a portable electronic device according to an embodiment of the present invention.

FIG. 2 is a perspective view illustrating the portable electronic device by reversing the apparatus in a closed state.

FIG. 3 is a perspective view illustrating a tilt state of the portable electronic device.

FIG. 4 is a perspective view illustrating a tilt state of the portable electronic device seen from a back surface side.

FIG. 5 is a perspective view illustrating a first open state of the portable electronic device.

FIG. 6 is a perspective view illustrating a first open state of the portable electronic device by reversing the apparatus.

FIG. 7 is a perspective view illustrating a second open state of the portable electronic device.

FIG. 8 is a perspective view illustrating a second open state of the portable electronic device by reversing the apparatus.

FIG. 9 is an exploded perspective view of the portable electronic device.

FIG. 10 is an exploded perspective view of the portable electronic device in a reversed state.

FIG. 11 is a perspective view of the portable electronic device in a further partly exploded state from a state of FIG. 10.

FIG. 12 is a perspective view of the portable electronic device in a further partly exploded state from a state of FIG. 11.

FIG. 13 is a cross-sectional view of the portable electronic device.

FIG. 14 is a perspective view of the portable electronic device in a partly exploded state from a state of FIG. 8.

FIG. 15 is a plan view illustrating a first open state of the portable electronic device.

FIG. 16 is a cross-sectional view of a relevant portion along a line C-C in FIG. 15, in a process of shifting from a first open state (a) to a second open state (c) via an intermediate state (b).

FIG. 17 is a cross-sectional view illustrating a deformed state of a flexible lead in a process of shifting from a closed state (a) to a second open state (c) via a first open state (b).

FIG. 18 is a perspective view illustrating a pair of projecting portions formed on a second casing in a closed state.

FIG. 19 is an enlarged perspective view illustrating a portion E in FIG. 18.

FIG. 20 is a plan view illustrating a pair of projecting portions formed on the second casing in a closed state.

FIG. 21 is an enlarged plan view illustrating a portion F in FIG. 20.

FIG. 22 is an enlarged cross-sectional view illustrating a relevant portion of the second casing at a position where a projecting portion is formed.

FIG. 23 is an enlarged cross-sectional view illustrating a hook structure that is arranged along an opposing portion between the first casing and the second casing in an open state.

FIG. 24 is a perspective view illustrating a state where a second display and a front surface cabinet are exploded from a holder member of the second display.

FIG. 25 is an exploded perspective view of a holder member and a frame member of the second display.

FIG. 26 is a perspective view of a state where the second display and the front surface cabinet are exploded from the holder member of the second display, seen from a direction different from a direction in FIG. 24.

FIG. 27 is an enlarged perspective view of the second display.

FIG. 28 is an enlarged perspective view along a line B-B in FIG. 27.

FIG. 29 is a cross-sectional view illustrating a mechanism that presses the second display to a first casing side.

FIG. 30 is a cross-sectional view illustrating a mechanism that presses the first display to a second casing side.

FIG. 31 is a cross-sectional view illustrating a close contact state of the first display and the second display in an open state.

FIG. 32 is a series of side views illustrating a first half of a process from a closed state to a second open state via a tilt state in the portable electronic device according to the present invention.

FIG. 33 is a series of side views illustrating a latter half of the above process.

FIG. 34 is a series of side views illustrating a first half of a process from a second open state to a closed state via a tilt state of the portable electronic device according to the present invention.

FIG. 35 is a series of side views illustrating a latter half of the above process.

FIG. 36 is a cross-sectional view illustrating a state immediately before the projecting portion of the second casing is engaged with a through-hole of a coupling member.

FIG. 37 is a cross-sectional view illustrating a state where the projecting portion of the second casing is engaged with the through-hole of the coupling member.

FIG. 38 is a perspective view illustrating a region of a relief surface that is formed on a back surface of the second casing.

FIG. 39 is a view schematically illustrating an inclined state of a flange surface in a closed state of both the casings.

FIG. 40 is a view illustrating a transition of the second casing in a shift process from a closed state to a tilt state.

FIG. 41 is a front view of a hinge unit.

FIG. 42 is a partially exploded font view of the hinge unit.

FIG. 43 is a view for explaining a first example of a cam curve of a cam mechanism that is incorporated in the hinge unit and its function.

FIG. 44 is a view for explaining a second example of a cam curve of a cam mechanism that is incorporated in the hinge unit and its function.

FIG. 45 is a view for explaining operations of a magnet and a magnetic sensor.

FIG. 46 is a side view illustrating states where the portable electronic magnetic apparatus according to the present invention is placed on a desk in a tilt state (a) and in a second open state (b).

FIG. 47 is an enlarged cross-sectional view illustrating shapes of a projecting portion formed on the first casing and a recessed portion formed on the second casing.

FIG. 48 is a cross-sectional view illustrating a first stage of a process of directly shifting from a second open state to a tilt state.

FIG. 49 is a cross-sectional view illustrating a second stage of a process of directly shifting from the second open state to the tilt state.

FIG. 50 is a cross-sectional view illustrating a third stage of a process of directly shifting from the second open state to the tilt state.

### DETAILED DESCRIPTION OF EMBODIMENTS

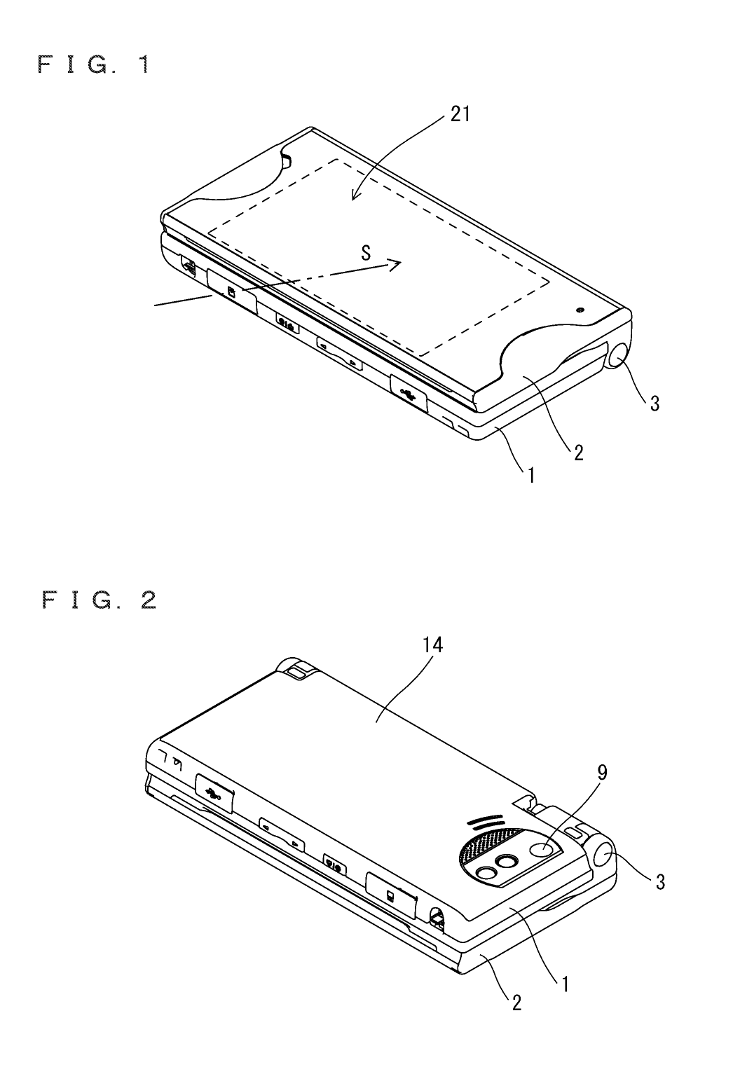

According to a portable electronic device according to an embodiment of the present invention, a first casing 1 that has a first display surface 11 on a surface and a second casing 2 that has a second display surface 21 on a surface are coupled to each other via a coupling mechanism 3, as illustrated in FIGS. 1 to 8. Not only images but also characters or videos can be displayed on the first display surface 11 and the second display surface 21.

As illustrated in FIG. 2, a battery lid 14 is arranged on a back surface of the first casing 1, and a photographing lens 9 is arranged by being exposed from the battery lid 14.

When specifying each portion of constituent elements of the portable electronic device in the following explanation, “front (nearside)”, “back”, “left”, and “right” of the portable electronic device illustrated in FIG. 1 when the apparatus is seen along a line of sight of the user indicated by an arrow S in the drawings are called “front”, “back”, “left”, and “right”, regardless of a posture of the portable electronic device, also in other drawings.

As illustrated in FIG. 13, inside the first casing 1, a first touch panel 13 and a first display 12 are arranged to face the first display surface 11, and a camera 91 is arranged to face the photographing lens 9. Further, a battery 15 is accommodated inside the first casing 1, and the battery 15 can be replaced by getting off the battery lid 14.

On the other hand, inside the second casing 2, a second touch panel 23 and a second display 22 are arranged to face the second display surface 21.

On a surface of the first touch panel 13, a glass plate 16 of a size larger than those of the first display 12 and the first touch panel 13 is set, and an image of the first display 12 is displayed by making a surface of the glass plate 16 as the first display surface 11.

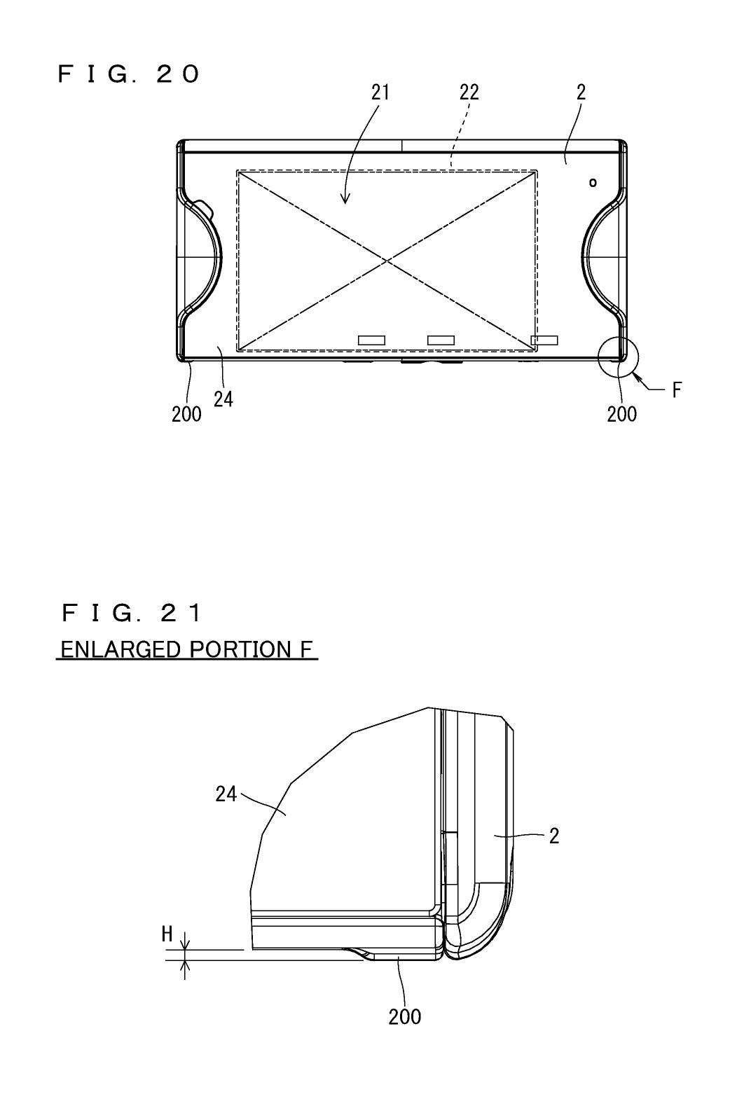

On a surface of the second touch panel 23, a glass plate 24 of a size larger than those of the second display 22 and the second touch panel 23 is set, and an image of the second display 22 is displayed by making a surface of the glass plate 24 as the second display surface 21 (see FIG. 20).

Surfaces 110, 110 of the first casing 1 are exposed to both sides of the glass plate 16 that is set on the first casing 1.

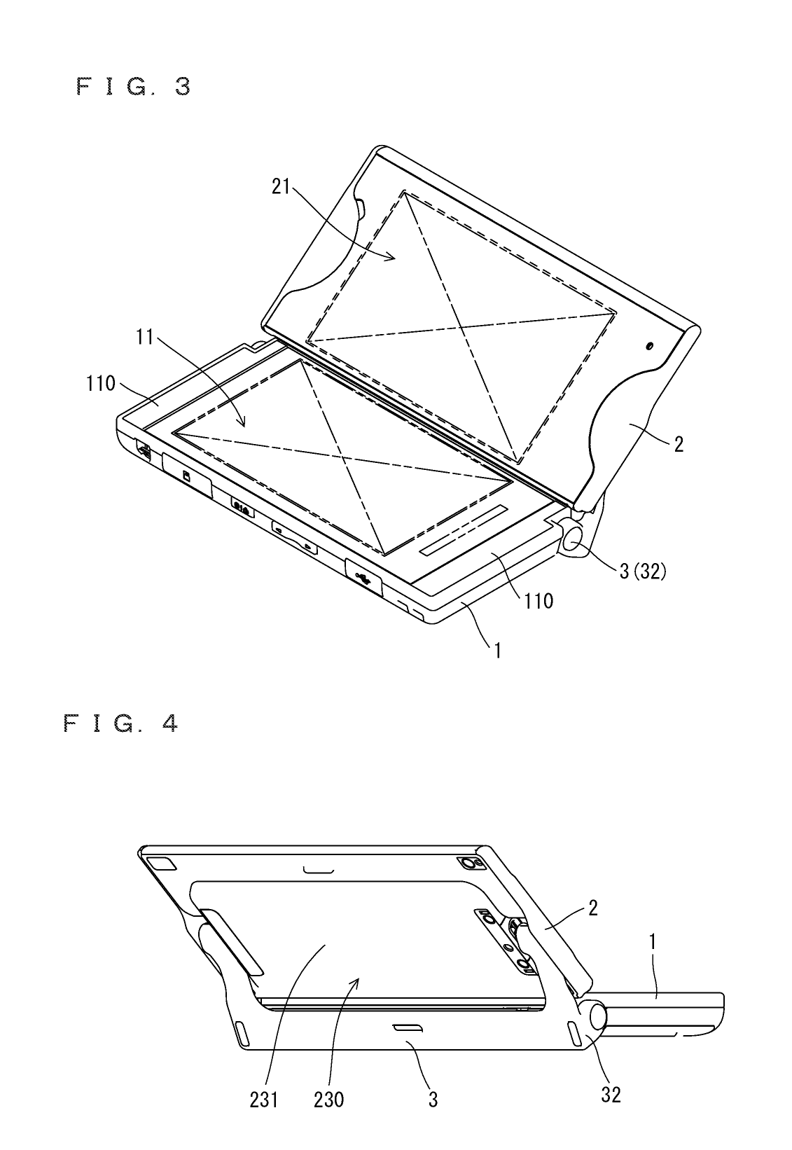

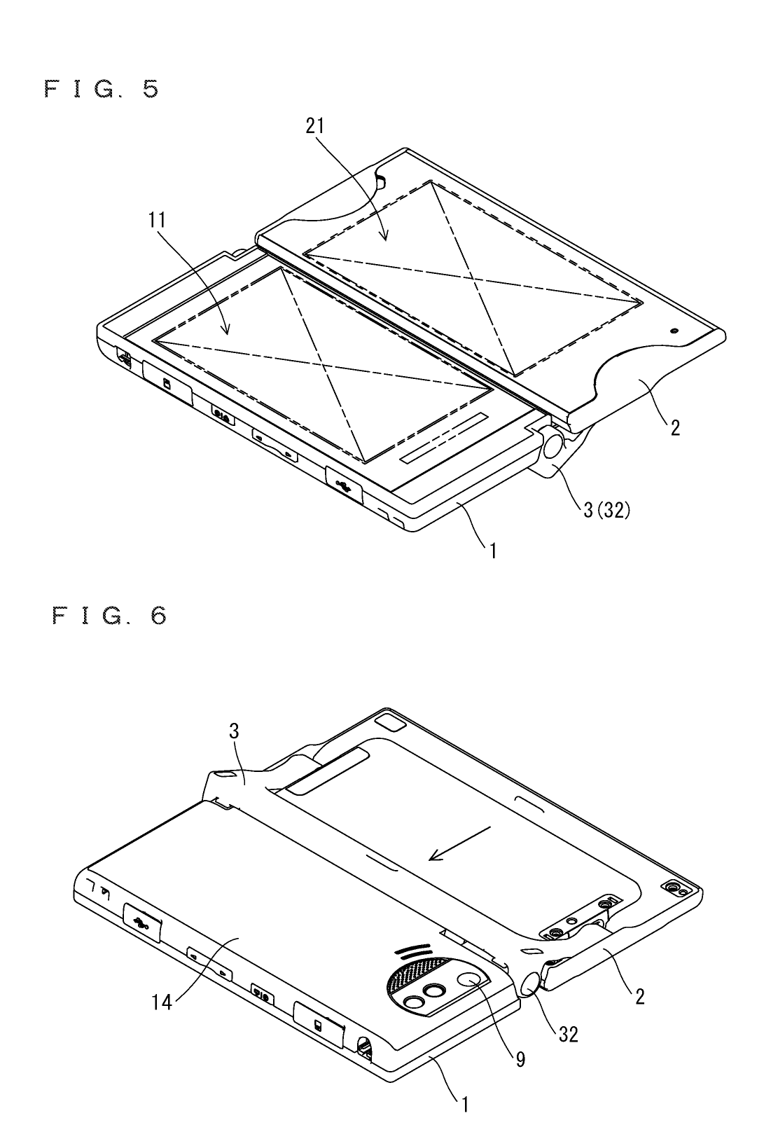

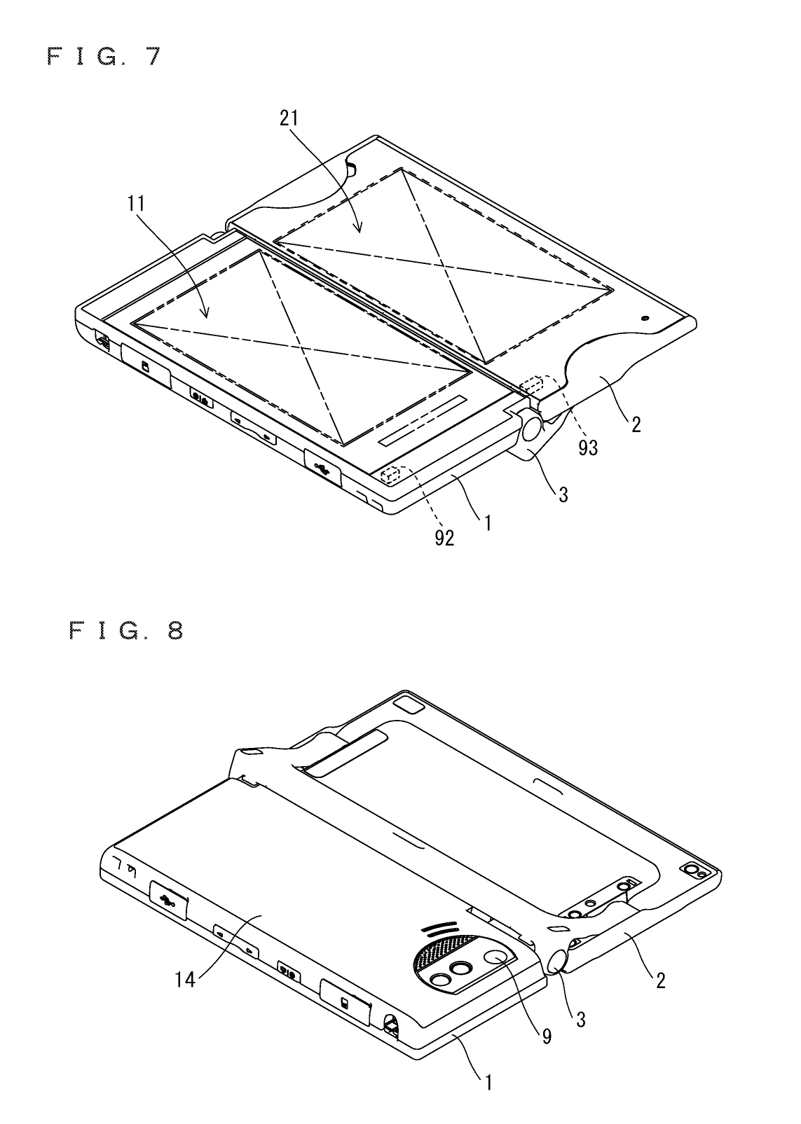

The portable electronic device according to the present invention can be selectively set in four states which include a closed state where the surface of the first casing 1 is covered with the back surface of the second casing 2 and also only the surface of the second casing 2 is exposed as illustrated in FIGS. 1 and 2, a tilt state where the surfaces of both the casings 1, 2 are exposed by moving the second casing 2 backward and also the surface of the second casing 2 is inclined with respect to the surface of the first casing 1 at an open angle equal to or larger than 90 degrees and smaller than 180 degrees as illustrated in FIGS. 3 and 4, a first open state where the surfaces of both the casings 1, 2 are exposed on the same plane by turning the second casing 2 backward as illustrated in FIGS. 5 and 6, and a second open state where the second casing 2 is slid to a first casing 1 side in a state where the surfaces of both the casings 1, 2 are exposed on the same plane as illustrated in FIGS. 7 and 8.

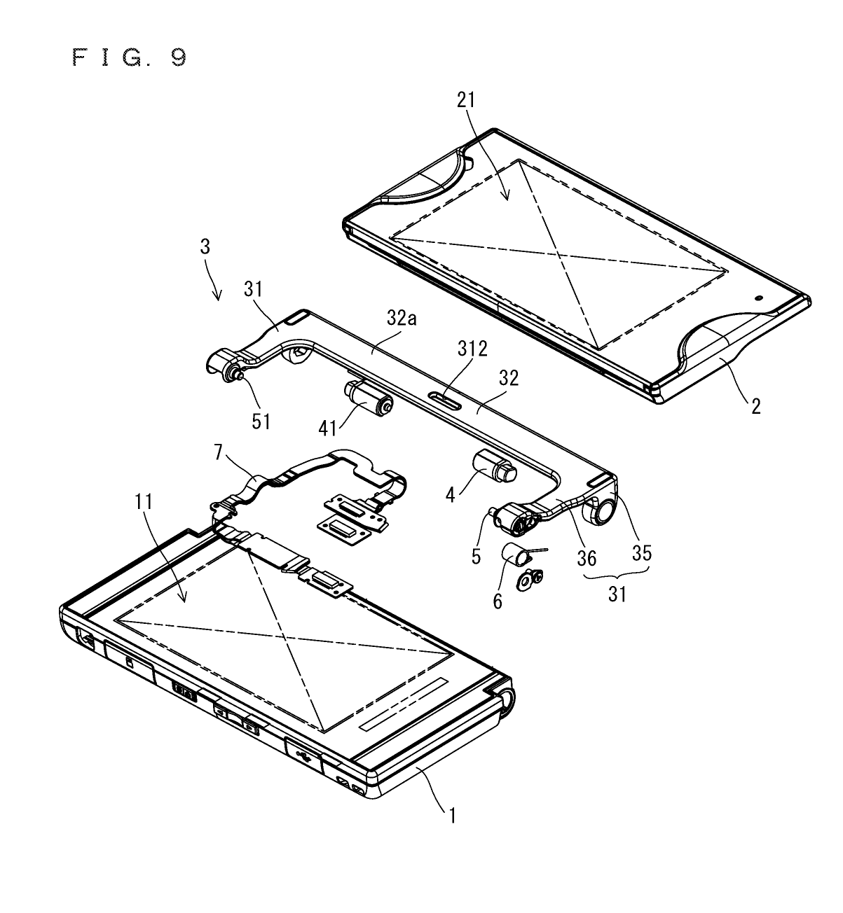

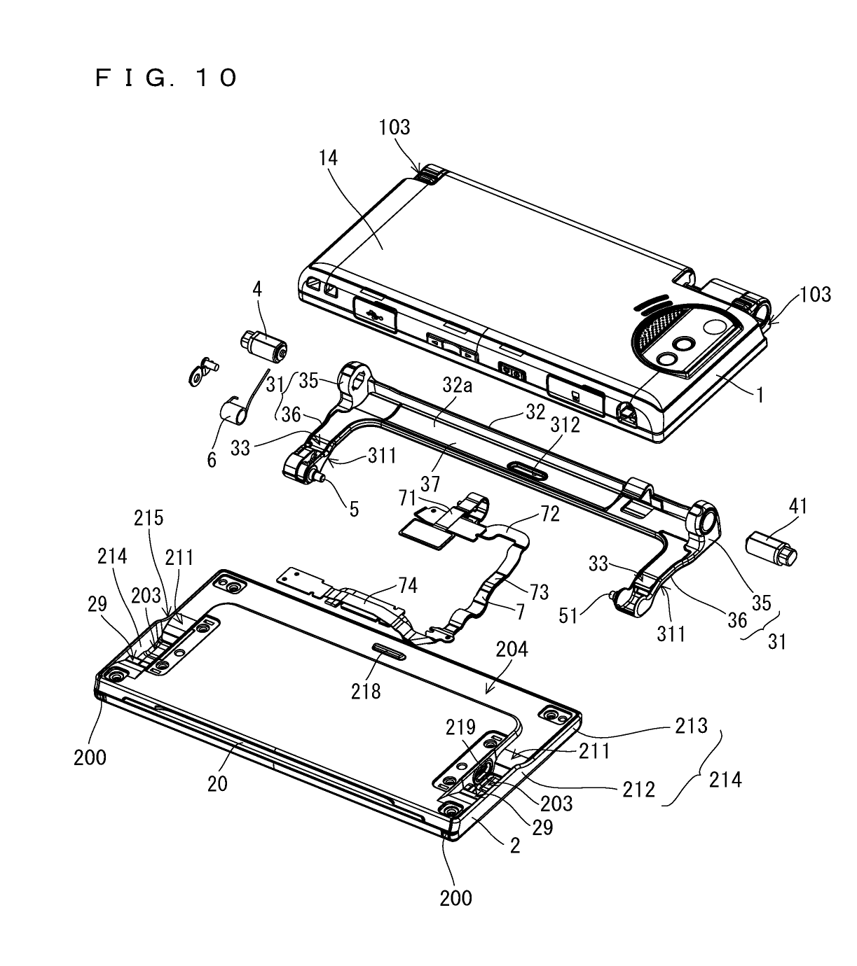

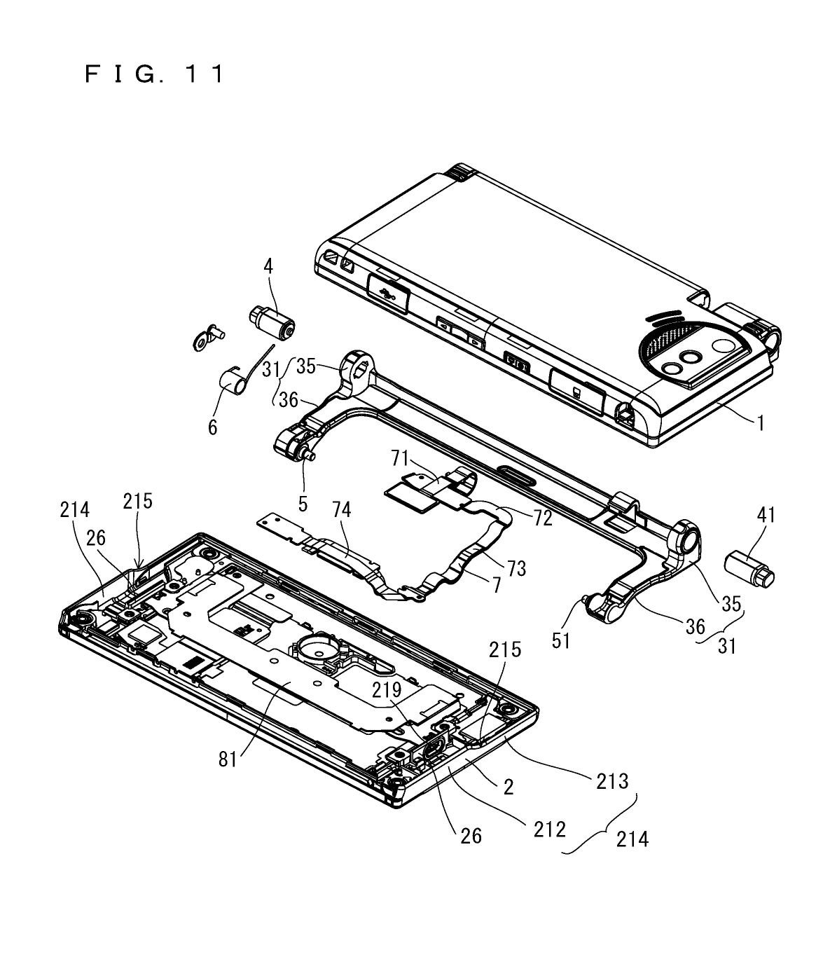

The coupling mechanism 3 that couples the first casing 1 and the second casing 2 to each other includes a U-shaped coupling member 32 that is formed by protruding a pair of left and right coupling arms 31 and 31 extended to forward and backward directions at both end portions of an arm coupling portion 32a which is extended to left and right, as illustrated in FIGS. 9 and 10.

The coupling arm 31 has an L-shape that is bent in an L-shape on a surface which is orthogonal to the display surfaces of both the casings, and the coupling arm 31 is configured by a first arm portion 35 and a second arm portion 36 that cross each other at a corner portion of the L-shape.

A base end portion (a base end portion of the first arm portion 35) of the coupling arm 31 at the right side is coupled to a right-side surface back end portion of the first casing 1 via a hinge unit 4 that incorporates a cam mechanism having a spring as described later, and a base end portion (a base end portion of the first arm portion 35) of the coupling arm 31 at the left side is coupled to a left-side surface back end portion of the first casing 1 via a dummy hinge unit 41 that does not incorporate a cam mechanism.

Further, a front end portion (a front end portion of the second arm portion 36) of the coupling arm 31 at the right side is coupled to a back-surface right end portion of the second casing 2 via a first hinge member 5, and a front end portion (a front end portion of the second arm portion 36) of the coupling arm 31 at the left side is coupled to a back-surface left end portion of the second casing 2 via a second hinge member 51.

The hinge units 4, 41 constitute a first axis that couples the base portions of the coupling arms 31 to the first casing 1, and the hinge members 5, 51 constitute a second axis that couples the front end portions of the coupling arms 31 to the second casing 2. The first axis and the second axis are in parallel with each other.

The second arm portion 36 of each coupling arm 31 has a slide contact surface 311 formed on an opposing portion that faces the second casing 2, and the second casing 2 is formed with a slide contact receiving surface 211 that faces the slide contact surface 311 in a closed state.

An electronic part incorporated in the first casing 1 and an electronic part incorporated in the second casing 2 are connected to each other by a flexible lead 7. The flexible lead 7 is extended from an inside of the first casing 1 to an inside of the second casing 2 via an inside of the coupling arm 31, and has a first lead portion 71 accommodated in the inside of the first casing 1, a second lead portion 72 accommodated in the inside of the coupling arm 31, and a third lead portion 73 accommodated in the inside of the second casing 2.

The flexible lead 7 has a length with a minimum necessary margin capable of allowing a relative movement of the first casing 1 and the second casing 2.

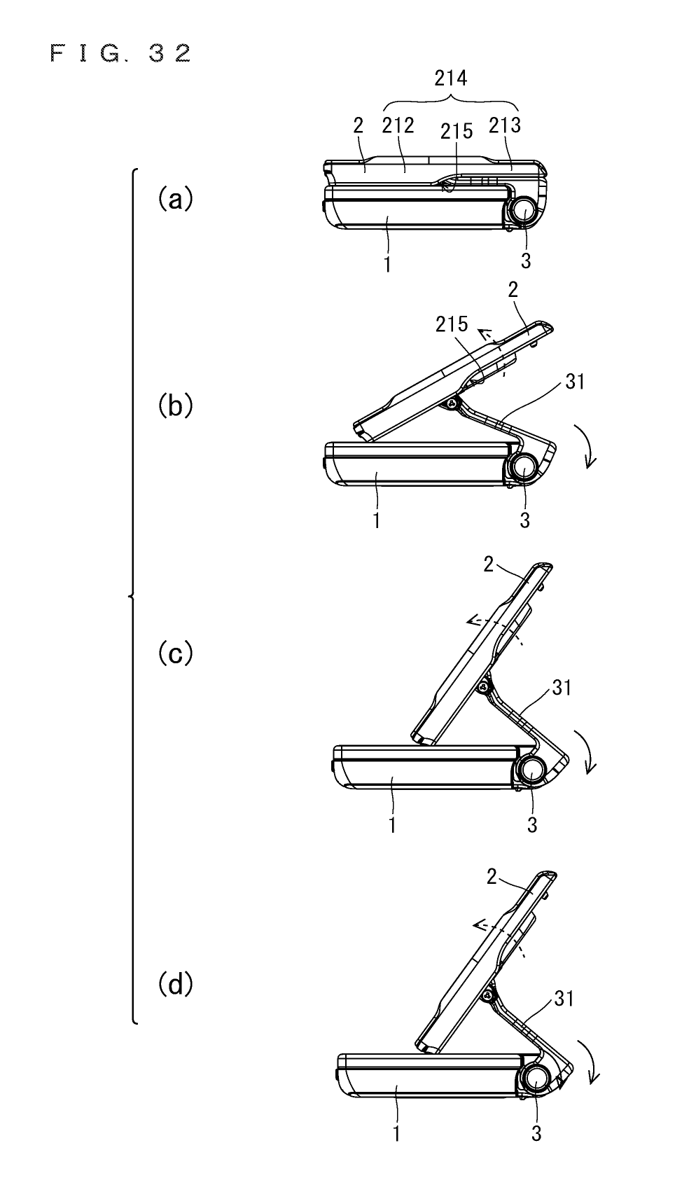

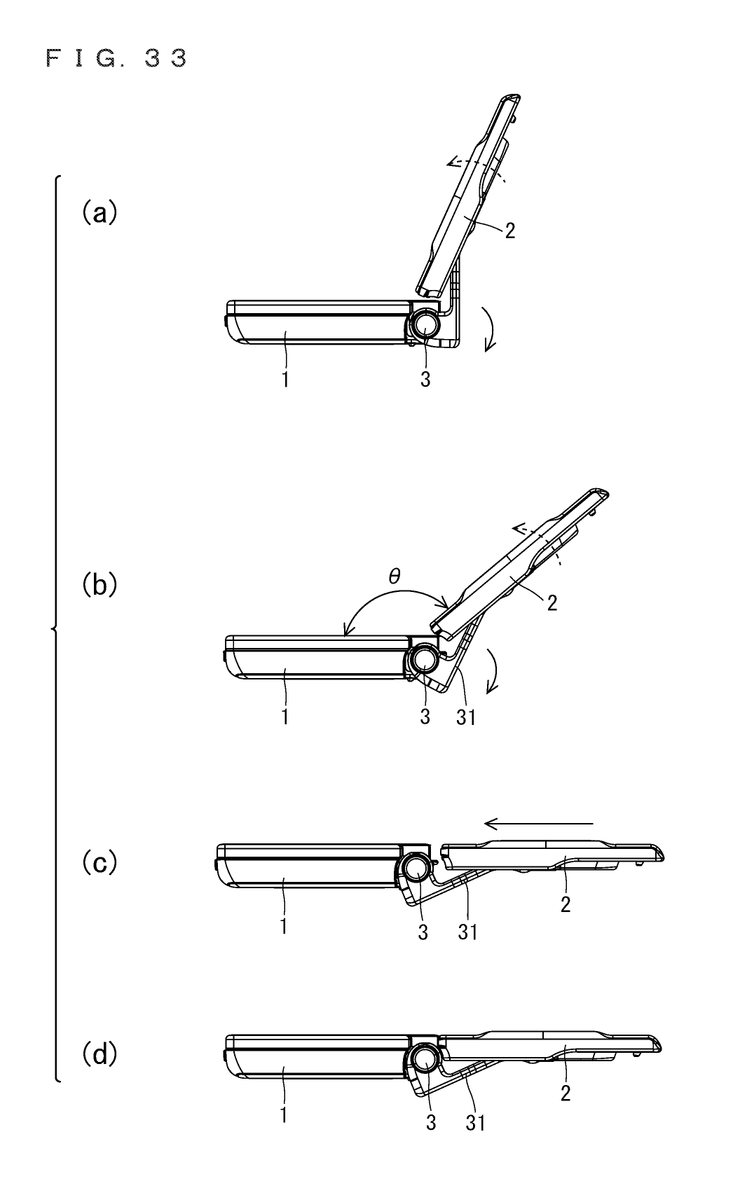

With this arrangement, a series of relative movements of the second casing 2 relative to the first casing 1 illustrated in FIG. 32(a) to (d) and FIG. 33(a) to (d) can be performed.

The hinge unit 4 softly latches the coupling member 32 with the first casing 1 in the tilt state illustrated in FIGS. 3 and 4, and also biases the coupling member 32 toward a turn angle in the tilt state within a constant angle range centered around a turn angle in the tilt state. Further, the hinge unit 4 biases the coupling member 32 toward a turn angle in the first open state within a constant angle range including the first open state illustrated in FIGS. 5 and 6.

In the first open state illustrated in FIGS. 5 and 6, the coupling member 32 is held at the turn angle in the first open state, based on the coupling member 32 being received by the first casing 1.

Specifically, the hinge unit 4 includes a fixed cam piece 42 and a movable cam piece 43 that can be turned relative to each other, and a cam surface 45 formed on the fixed cam piece 42 and a cam surface 46 formed on the movable cam piece 43 face each other.

Between the fixed cam piece 42 and the movable cam piece 43, a spring 47 that brings the cam surfaces 45, 46 of the cam pieces 42, 43 in pressure-contact with each other is interposed. A torque that turns the cam pieces 42, 43 relative to each other occurs based on a bias of the spring 47 and slide contact between the cam surfaces 45, 46.

The fixed cam piece 42 and the movable cam piece 43 of the hinge unit 4 are coupled to the second arm portion 36 of the coupling arm 31 and a side portion of the first casing 1, respectively shown in FIG. 9.

In this way, the hinge unit 4 constituting the coupling mechanism 3 incorporates the cam mechanism having the spring, and the hinge unit 4 applies a torque as resistive force or bias force to the turn of the second casing 2 with respect to the first casing 1.

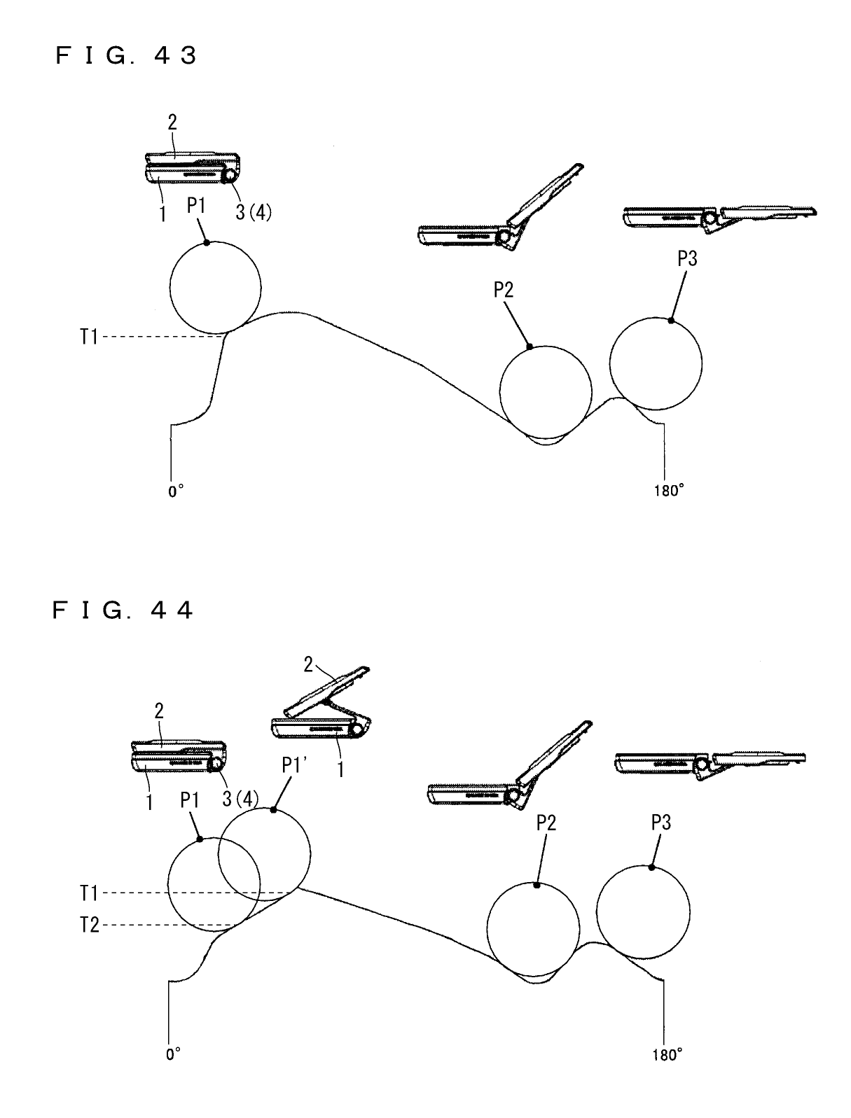

The cam mechanism incorporated in the hinge unit 4 operates following a cam curve illustrated in FIG. 43 or FIG. 44. The cam curve has two crest portions and a valley portion which is interposed between the two crest portions, within an angle range of 0° to 180°.

A large crest portion (a first crest portion) at a 0° side of the cam curve functions in a shift process from a closed state to a tilt state. In the closed state, the crest portion holds the first casing 1 and the second casing 2 in the closed state, by an inclined portion (a cam state P1) at the 0° side of the crest portion. After passing through an intermediate state between the closed state and the tilt state, the crest portion biases the first casing 1 and the second casing 2 toward a tilt state.

A small crest portion (a second crest portion) at a 180° side of the cam curve functions in a shift process from a tilt state to the first open state. In the first open state, the crest portion holds the first casing 1 and the second casing 2 in the first open state, by an inclined portion (a cam state P3) at the 180° side of the crest portion.

By a valley portion (a cam state P2) of the cam curve, the first casing 1 and the second casing 2 are held in a tilt state.

In the cam curve of a first example illustrated in FIG. 43, a torque which is generated by the cam mechanism in the closed state is set to a value slightly larger than a first torque value T1 that works to the cam mechanism based on an own weight of the first casing 1 when only the second casing 2 is grasped and raised.

On the other hand, in the cam curve of a second example illustrated in FIG. 44, an inclined portion (a cam state P1′) immediately before a crest portion of a first crest portion functions, in an intermediate state between a closed state and a tilt state. A torque which is generated by the cam mechanism in an intermediate state between the closed state and the tilt state is set to a value larger than a first torque value T1 that works to the cam mechanism based on an own weight of the first casing 1 when only the second casing 2 is grasped and raised. A torque which is generated by the cam mechanism in the closed state is set to a second torque value T2 smaller than the torque value T1.

As illustrated in FIG. 9, a torsion spring 6 is fitted to the first hinge member 5, around a turn axis (a second axis) of the first hinge member 5. By the torsion spring 6, the second casing 2 is turn-biased to a direction of reducing an angle θ in a tilt state illustrated in FIG. 33(b).

As illustrated in FIG. 10, at both side-surface back end portions of the first casing 1, accommodation portions 103, 103 for accommodating the first arm portions 35, 35 of the coupling arms 31, 31 of the coupling member 32 are recessed.

On the other hand, at back-surface both side portions of the second casing 2, accommodation portions 204, 203, 203 for accommodating the arm coupling member 37 and the second arm members 36, 36 of the coupling member 32 are recessed.

Further, a through-hole 312 of a large lateral length is opened at a center portion of the arm coupling portion 32a of the coupling member 32. At the same time, in the second casing 2, a projecting portion 218 of a large lateral length to be engaged with the through-hole 312 in a closed state is formed at a center portion of the accommodation portion 204.

Each of both sidewalls 214, 214 of the second casing 2 has a first sidewall portion 212 having a large height from the surface of the second casing 2 toward a first casing 1 side, and a second sidewall portion 213 having a small height from the surface of the second casing 2 toward a first casing 1 side in a closed state. A pair of the first sidewall portions 212, 212 at left and right are positioned at both sides of the accommodation portions 203, 203 at both sides of the second casing 2.

A finger hang surface 215 inclined with respect to the surface of the first casing 1 in a closed state is formed between an end surface of the first sidewall portion 212 and an end surface of the second sidewall portion 213 that face the surface of the first casing 1.

As illustrated in FIG. 10, on each of the coupling arms 31, 31 of the coupling member 32, a receiving surface 33 for receiving the second casing 2 is formed at an opposing portion that faces the second casing 2. A slide surface 29 to be in slide contact with the receiving surface 33 is formed on each of the back-surface both end portions of the second casing 2.

In the tilt state illustrated in FIGS. 3 and 4, and in the first open state illustrated in FIGS. 5 and 6, the slide surface 29 of the second casing 2 is brought into contact with the receiving surface 33 of the coupling arm 31, and a turn of the second casing 2 to the coupling arm 31 is received. With this arrangement, a relative posture of the second casing 2 relative to the coupling arm 31 in the tilt state and the first open state is determined.

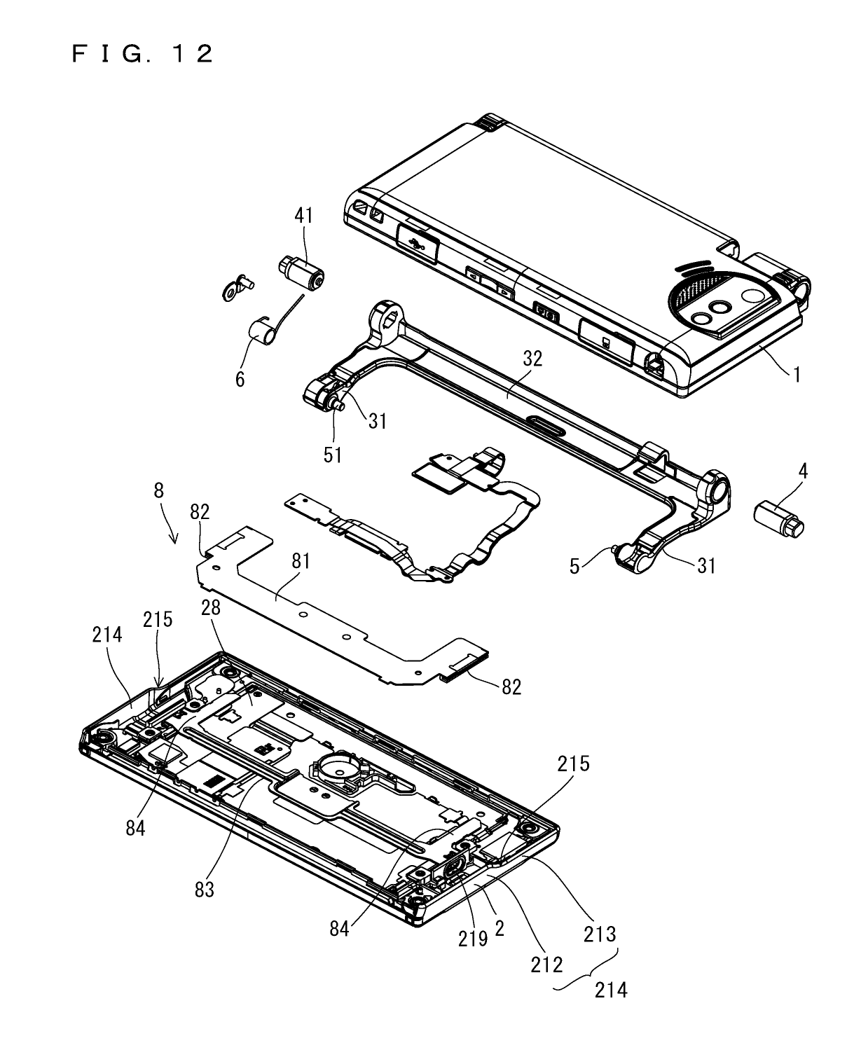

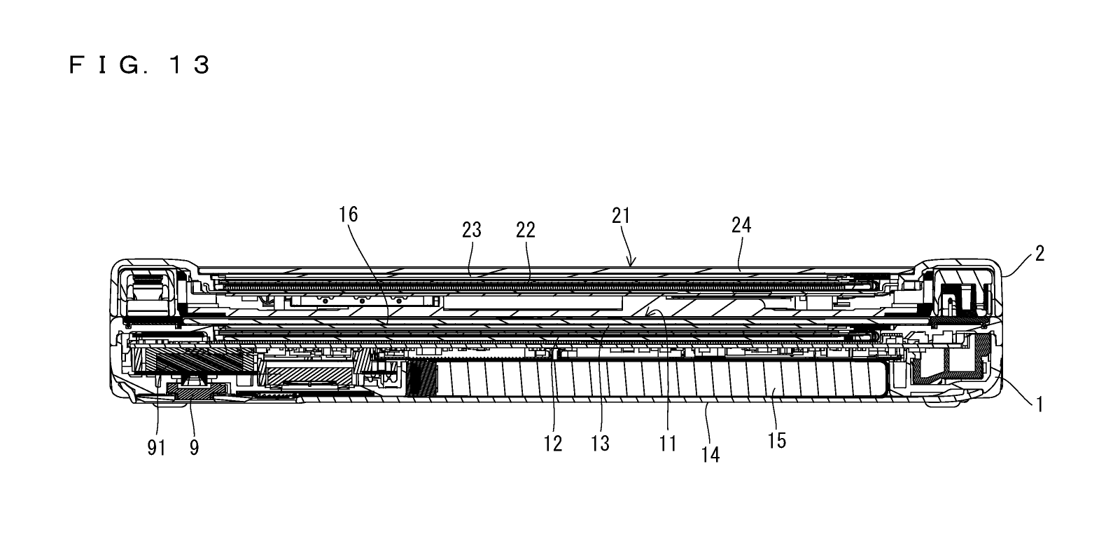

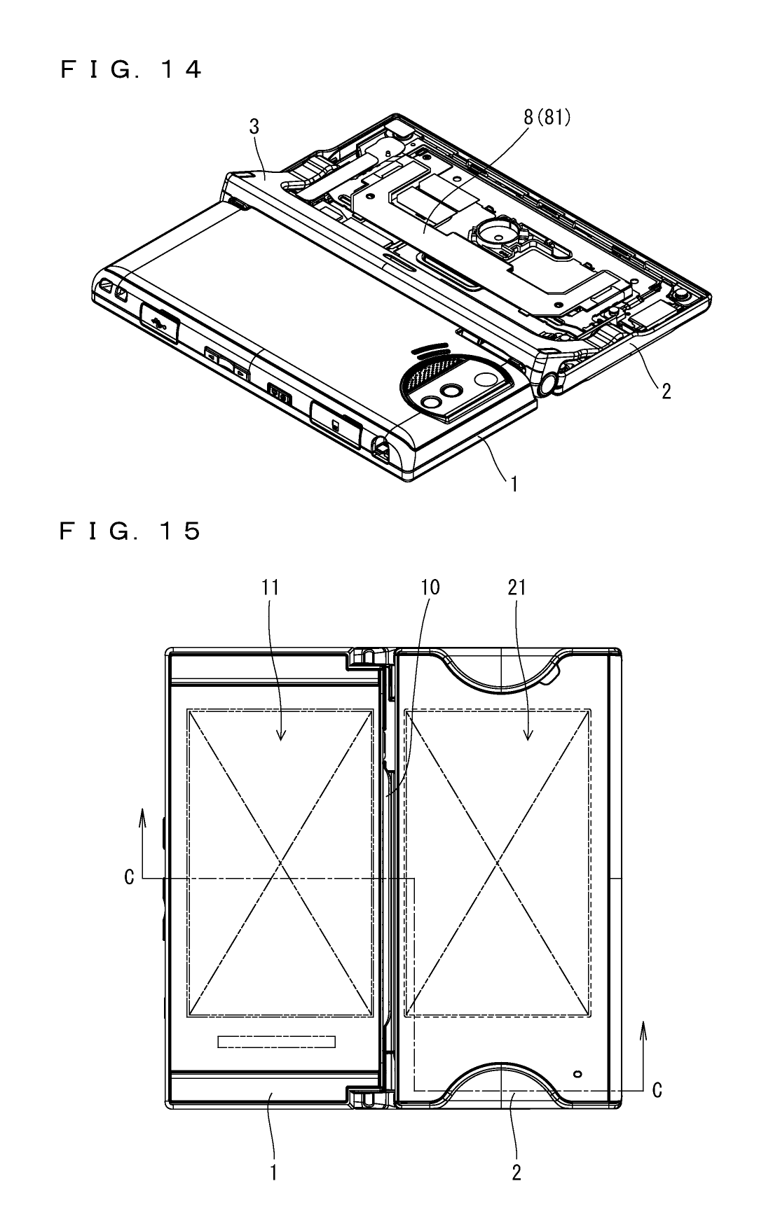

As illustrated in FIG. 12, on a plate metal member 28 set in the inside of the second casing 2, a U-shape sliding member 83 slidable in forward and backward directions is arranged, and also a U-shaped supporting member 81 is fixed by covering the sliding member 83 (see FIG. 14).

As illustrated in FIG. 12, arm members 84, 84 are provided in protrusion at both left and right end portions of the sliding member 83. Further, slide guide members 82, 82 are fitted to both left and right end portions of the supporting member 81.

The arm members 84, 84 of the sliding member 83 are sandwiched between the slide guide members 82, 82 of the supporting member 81 and the plate metal member 28, and slide of the sliding member 83 on the plate metal member 28 in forward and backward directions is guided.

The first hinge member 5 and the second hinge member 51 respectively penetrate through a long hole 219 on the second casing 2, and front end portions of the hinge members are axially coupled to both side portions of the arm portions 84, 84 of the sliding member 83.

Accordingly, a sliding mechanism 8 for sliding the second casing 2 to the arm members 84, 84 of the sliding member 83 in forward and backward directions is configured. The second casing 2 can be slid in forward and backward directions, between the first open state illustrated in FIGS. 5 and 6 and the second open state illustrated in FIGS. 7 and 8.

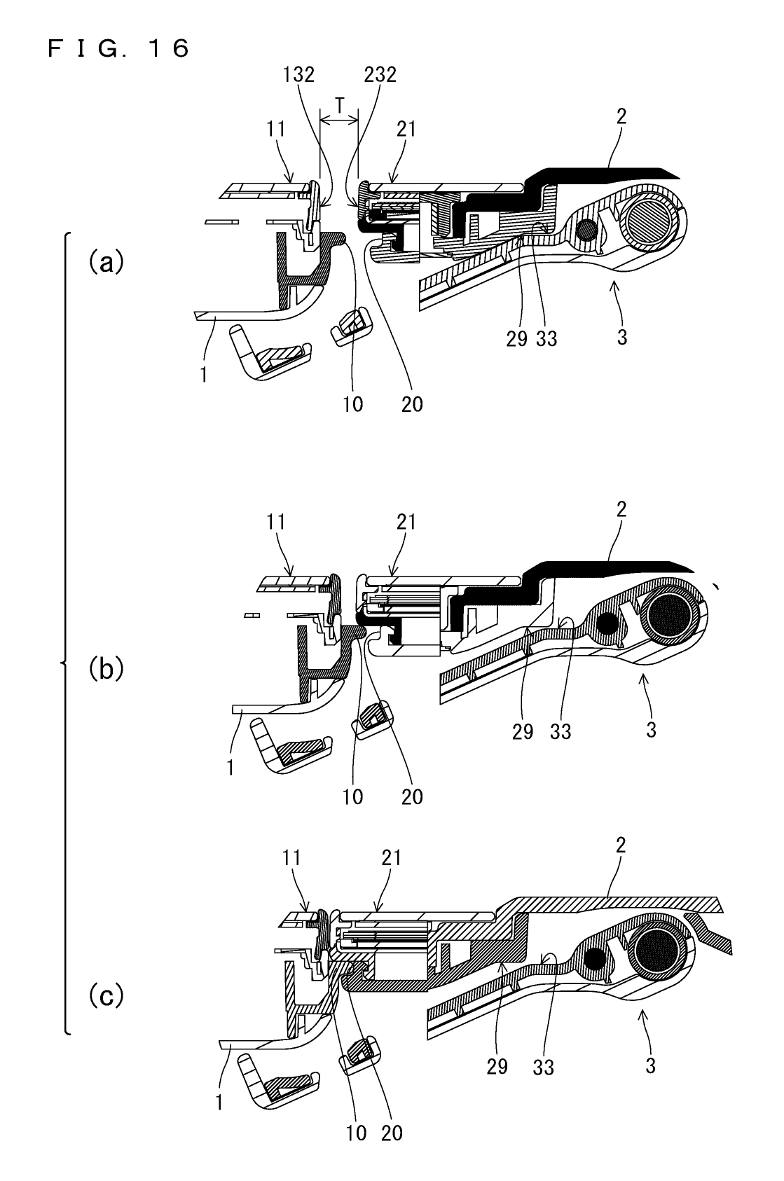

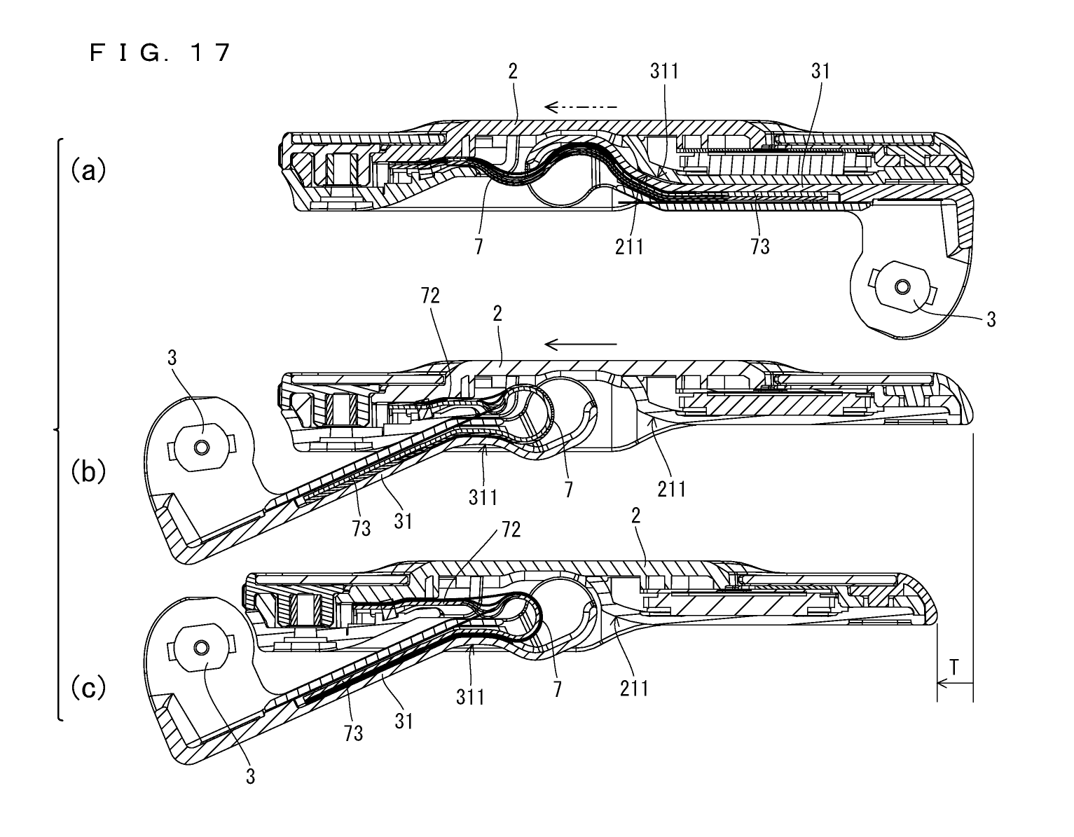

A projecting portion 10 that is protruded toward a front end surface of the first casing 1 in the first open state is formed as illustrated in FIG. 15, on a back end surface of the first casing 1 that faces the second casing 2 in the first open state. On the other hand, a recessed portion 20 as illustrated in FIG. 10 is formed, on a front end surface of the second casing 2 that faces the first casing 1 in the first open state. The projecting portion 10 and the recessed portion 20 can be engaged with and disengaged from each other as illustrated in FIG. 16(a), (b), and (c).

In the first open state illustrated in FIG. 16(a), the projecting portion 10 and the recessed portion 20 are separated from each other, and in the second open state illustrated in FIG. 16(c), the projecting portion 10 and the recessed portion 20 are engaged with each other. Accordingly, the first casing 1 and the second casing 2 are coupled to each other, and a state where the first display surface 11 and the second display surface 21 are arranged on the same plane is maintained.

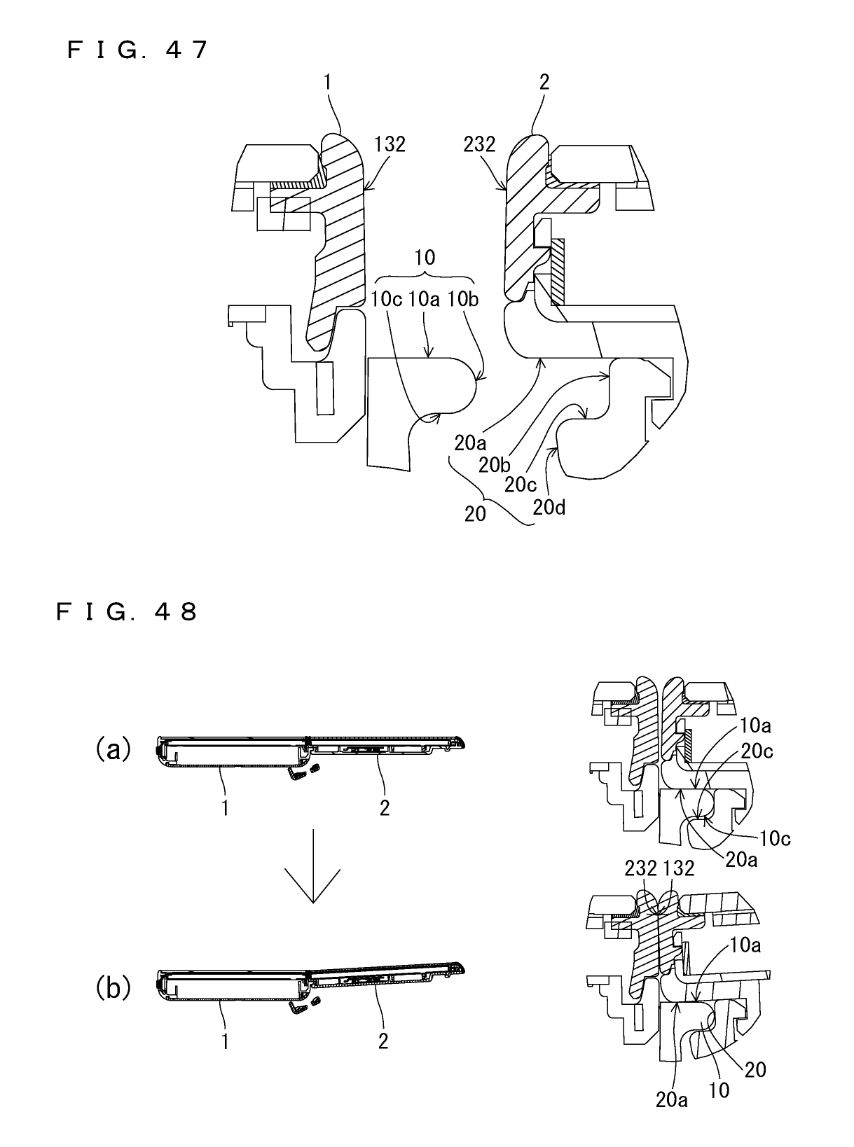

Specifically, as illustrated in FIG. 47, the projecting portion 10 has a first engagement surface 10a which is formed in parallel with the surface of the first casing 1 on an upper surface of the projecting portion 10, a second engagement surface 10b which is protruded in an arc shape toward the second casing 2, and a third engagement surface 10c which is formed in parallel with the surface of the first casing 1 on a lower surface of the projecting portion 10.

The recessed portion 20 has a first engagement receiving surface 20a capable of being in slide contact with the first engagement surface 10a of the projecting portion 10, a second engagement receiving surface 20b that faces a second engagement surface 10b of the projecting portion 10, a third engagement receiving surface 20c capable of being in slide contact with a third engagement surface 10c of the projecting portion 10, and a fourth engagement receiving surface 20d that is bent and extended downward from the third engagement receiving surface 20c.

In the first open state as illustrated in FIG. 16(a), a gap T of a sufficiently large size (a few millimeters, for example) is provided between an end surface 132 of the first casing 1 and an end surface 232 of the second casing. However, in the second open state as illustrated in FIG. 16(c), the end surfaces 132, 232 of both the casings 1, 2 are brought into contact with each other or face with each other by a slight distance (0.1 mm, for example).

According to the above portable electronic device, a posture of the second casing 2 is stable in a process of pulling the second casing 2 to a first casing 1 side in the first open state, and the posture of the second casing 2 to the first casing 1 is constantly held in the second open state in which the second casing 2 is closest to the first casing 1.

Further, in shifting the portable electronic device to a tilt state from the second open state in which the second casing 2 is displaced to the first casing 1, the apparatus can be directly shifted from the second open state to the tilt state, by only applying turning force to the second casing 2 without separating the second casing 2 from the first casing 1. Therefore, the operation becomes simple.

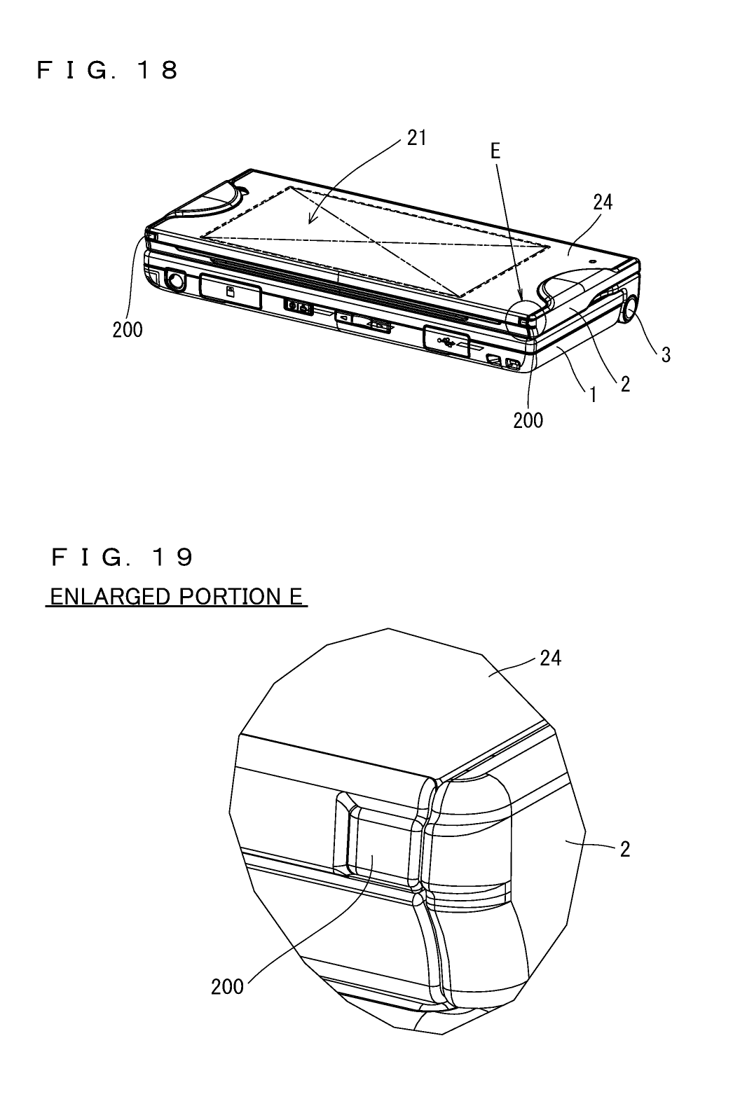

Further, in the portable electronic device, a pair of projecting portions 200, 200 are formed at both left and right end portions on the front end surface of the first casing 1, as illustrated in FIGS. 18 to 21. A protrusion height H of the projecting portion 200 is about 0.3 mm.

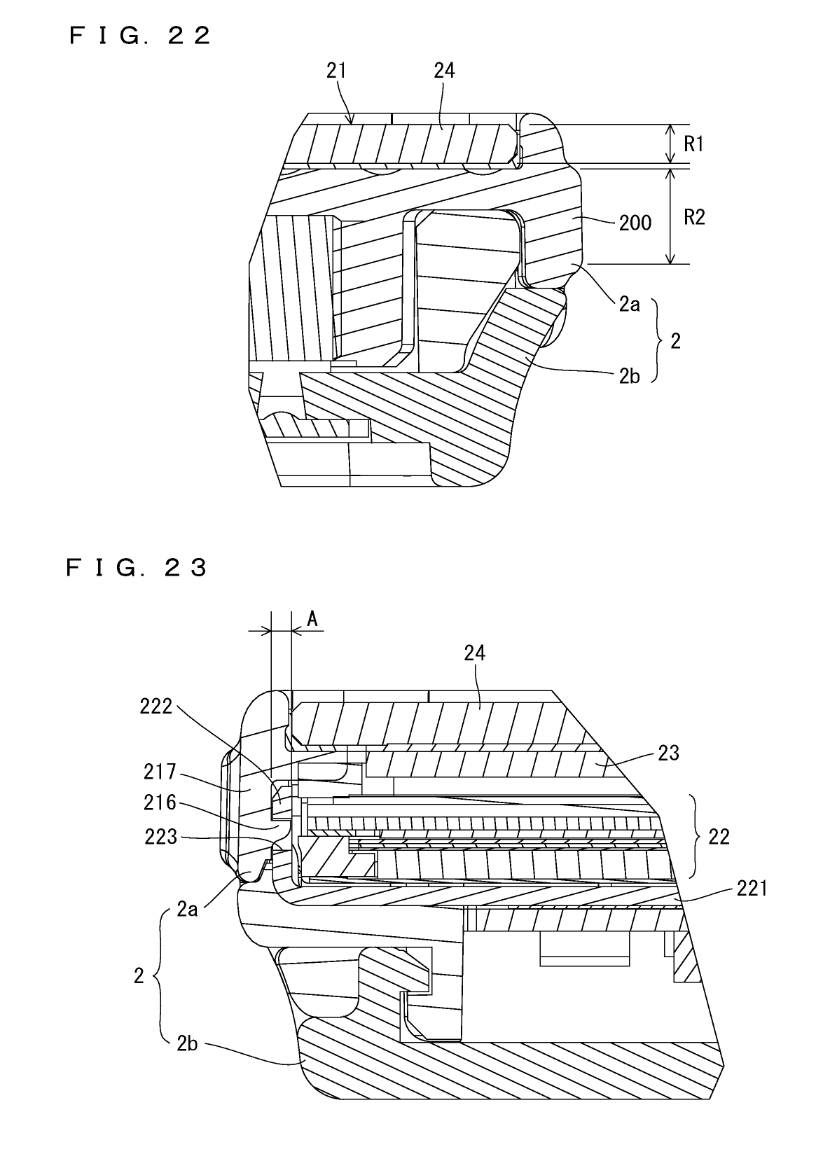

More specifically, as illustrated in FIG. 22, the second casing 2 is configured by a front surface cabinet 2a and a back surface cabinet 2b made of a synthetic resin respectively. The pair of projecting portions 200, 200 are formed on the front surface cabinet 2a, and are laid out in a region R2 deviated from a thickness region R1 of the glass plate 24 of the front surface cabinet 2a, and at positions deviated from a second display 22 to a width direction of the display 22 as illustrated in FIG. 20.

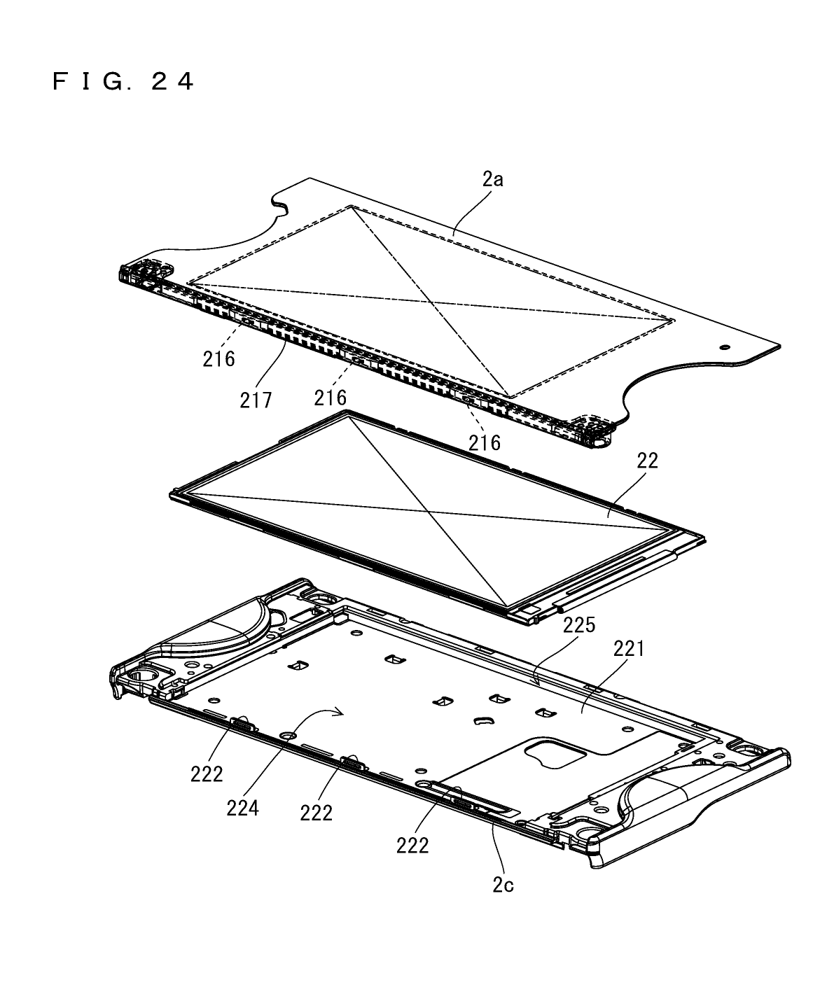

As illustrated in FIGS. 23 and 24, the second display 22 is held on a holder member 221 made of a plate (a plate thickness 0.3 mm) of stainless steel, and the holder member 221 is latched with the front surface cabinet 2a of the second casing 2.

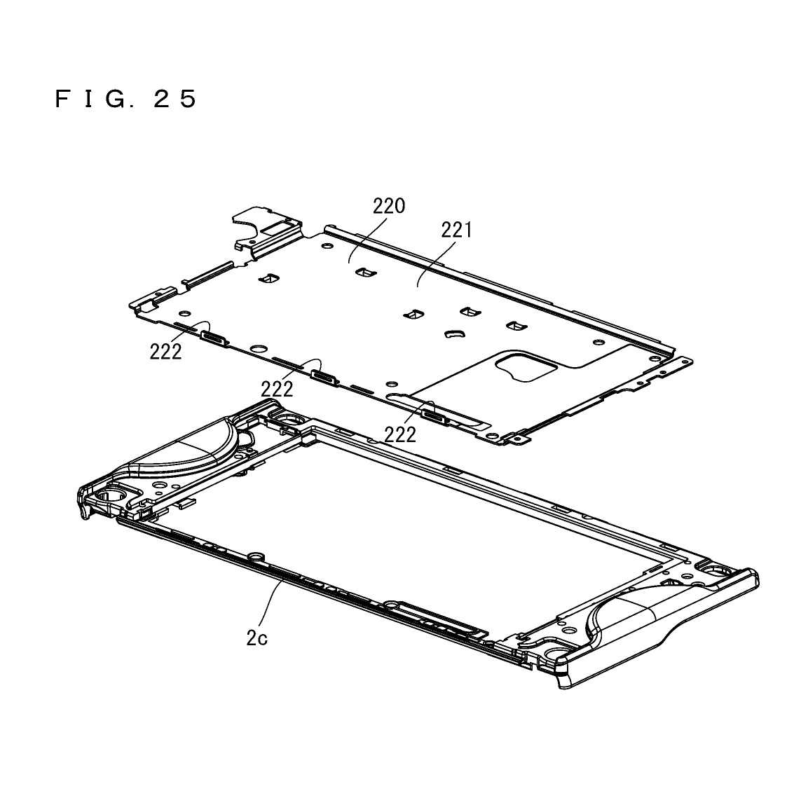

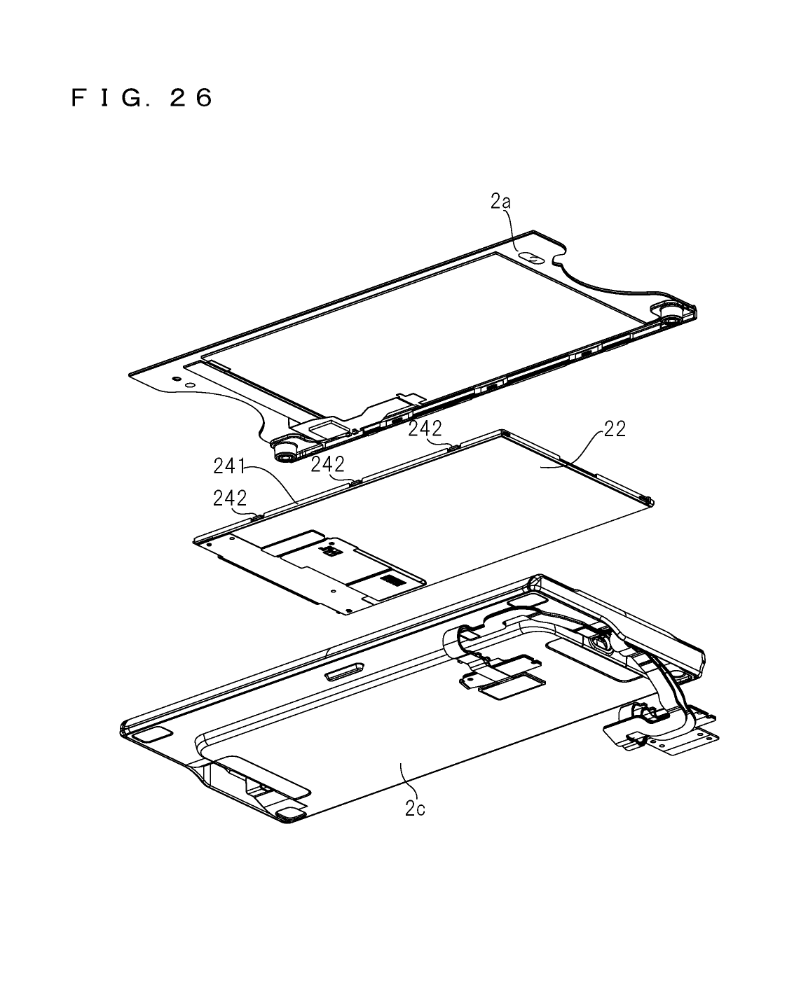

Specifically, the holder member 221 is engaged with a rack-shaped frame member 2c made of a synthetic resin illustrated in FIG. 25, and three engagement receiving pieces 222, 222, 222 are provided upward in protrusion, at an end edge at a front side of a plane portion 220 on which the second display is to be mounted.

On the other hand, as illustrated in FIGS. 23 and 24, a sidewall 217 extending along an end edge at a front side of the second display 22 is formed on the front surface cabinet 2a of the second casing 2. On an inner surface of the sidewall 217, three engaging pieces 216, 216, 216 to be engaged with the three engagement receiving pieces 222, 222, 222 are provided in protrusion toward the second display 22.

As illustrated in FIG. 23, in a state of engagement between the engagement receiving piece 222 and the engaging piece 216, the holder member 221 is latched with the front surface cabinet 2a of the second casing 2, based on engagement of the engaging piece 216 with a hole 223 opened on the engaging piece 222.

For example, an engagement depth (a plate thickness of the holder member 221) A between the engaging piece 216 and the engagement receiving piece 222 is set to 0.3 mm.

As illustrated in FIG. 24, an accommodation chamber 224 for accommodating the second display is recessed on the rack-shaped frame member 2c of the second casing 2.

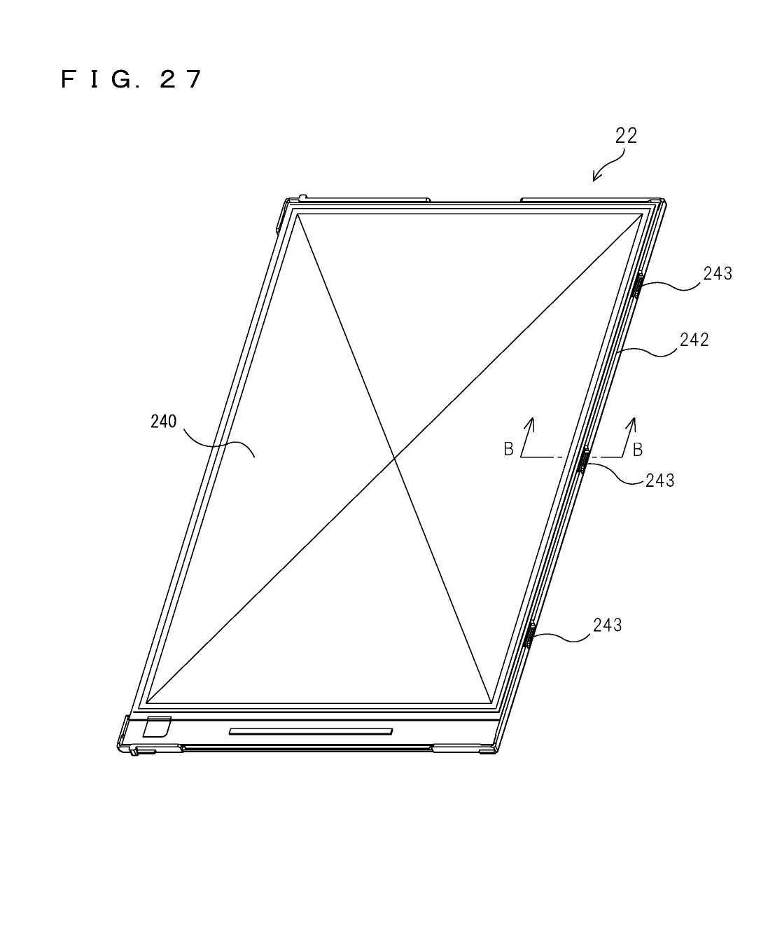

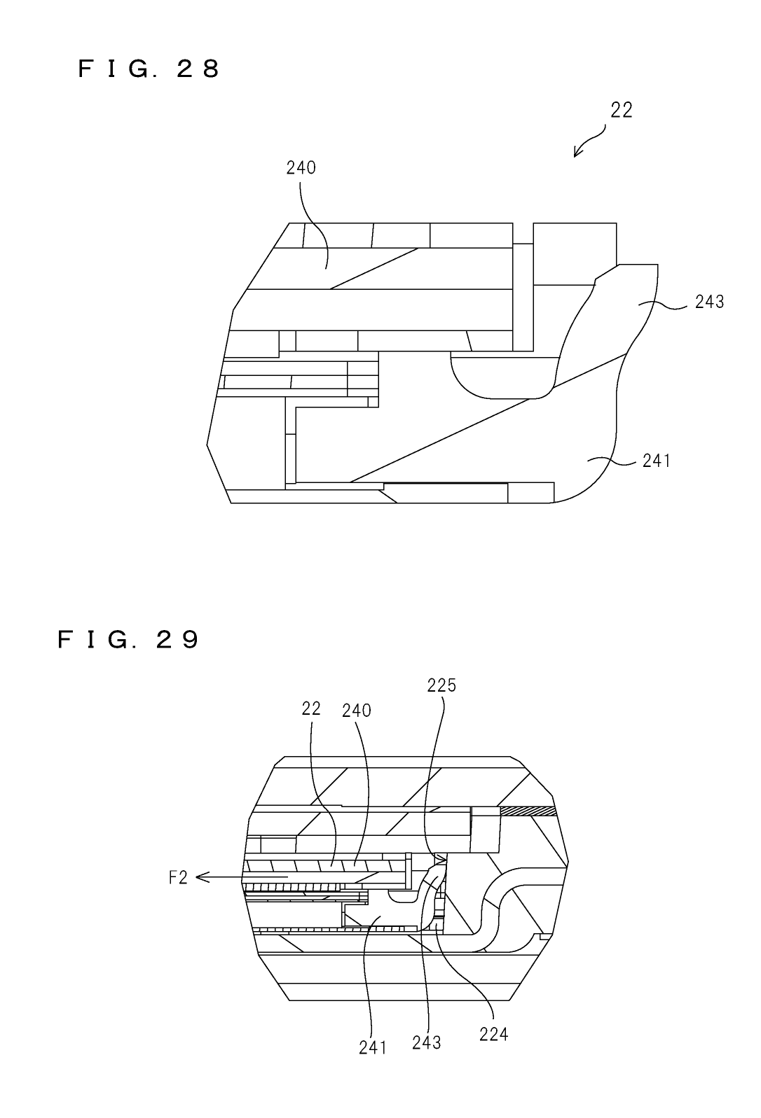

The second display 22 is configured by a display main body 240 and a frame portion 241 made of a synthetic resin for holding an external peripheral portion of the display main body 240, and three elastic pieces 243, 243, 243 to be bent backward are integrally molded on a frame portion 242 at a backside of the frame unit 241, as illustrated in FIGS. 27 and 28.

As illustrated in FIG. 29, a front end portion of each elastic piece 243 is brought into pressure-contact with an internal peripheral wall 225 of the accommodation chamber 224, in a state where the second display 22 is accommodated in the accommodation chamber 224, and the second display 22 is pressed forward (to a first casing side) by pressing force F2 caused by elastic repulsive force of the elastic piece 243.

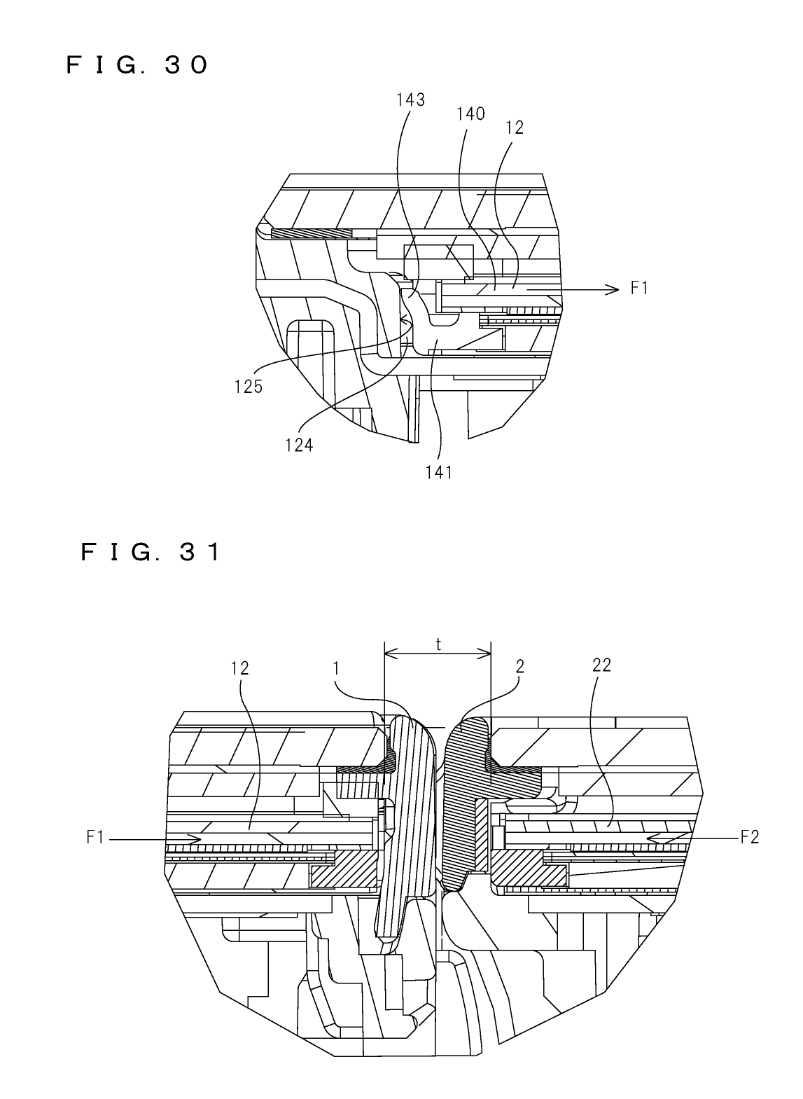

The first display 22 is configured by a display main body 140 and a frame portion 141 made of a synthetic resin for holding an external peripheral portion of the display main body 140, and three elastic pieces 143, 143, 143 to be bent forward are integrally molded on a frame portion at a front side of the frame unit 141, as illustrated in FIG. 30.

A front end portion of each elastic piece 143 is brought into pressure-contact with an internal peripheral wall 125 of the accommodation chamber 124, in a state where the first display 12 is accommodated in the accommodation chamber 124, and the first display 12 is pressed backward (to a second casing side) by pressing force F1 caused by elastic repulsive force of the elastic piece 143.

In this way, a pressing mechanism for pressing the first display 12 to a second casing 2 side in the open state is configured by the three elastic pieces 143, 143, 143.

As a result, in the open state illustrated in FIG. 31, the first display 12 is pressed to a second casing 2 side by the pressing force F1, and the second display 22 is pressed to a first casing 1 side by the pressing force F2. The first display 12 and the second display 22 are brought close to each other within a range of allowance in the respective accommodation chambers 124, 224, and a gap t between the displays 12 and 22 is minimized.

According to the portable electronic device, in the case of displaying an image by using two display surfaces of the first casing 1 and the second casing 2 as one screen in the second open state where the display surfaces of the first casing 1 and the second casing 2 are exposed on the same plane, a discontinuity of the image can be minimized.

Further, on a back surface 231 of the second casing 2 illustrated in FIG. 4, a relief surface 230 illustrated in FIG. 39 is formed at a lower end portion (an end portion at a front side) that is to move along the surfaces 110, 110 of the first casing 1 illustrated in FIG. 3 when a closed state is shifted to a tilt state. The relief surface 230 is inclined with respect to a direction of being separated from the surface of the first casing 1 in the closed state.

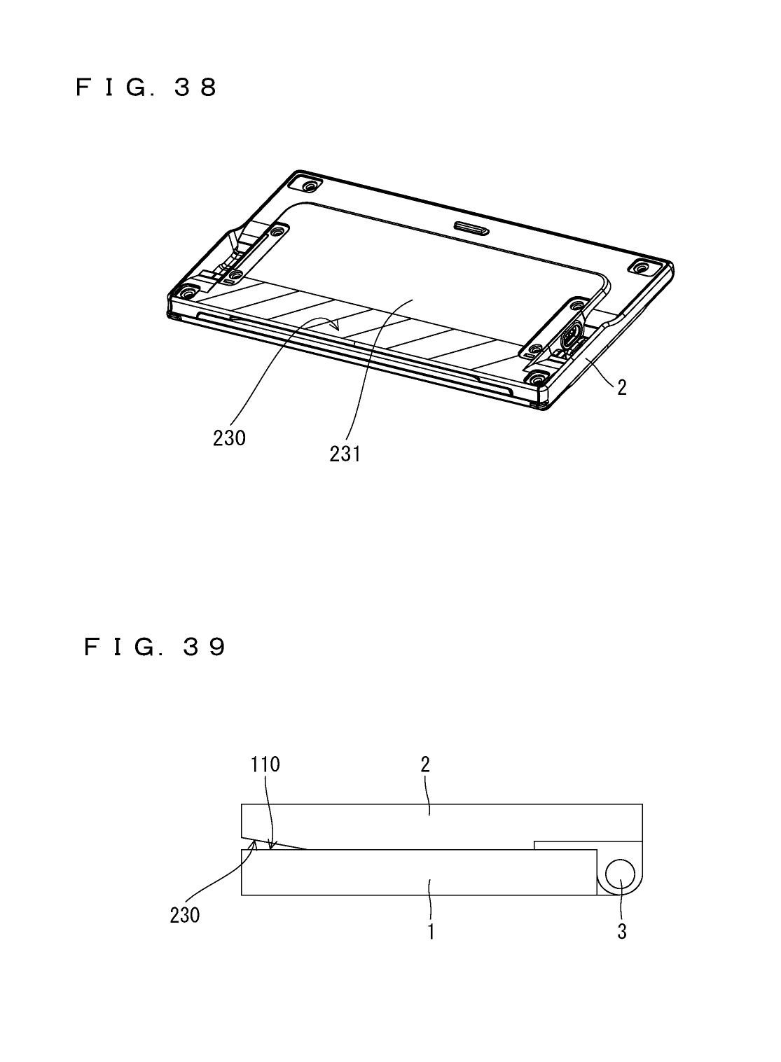

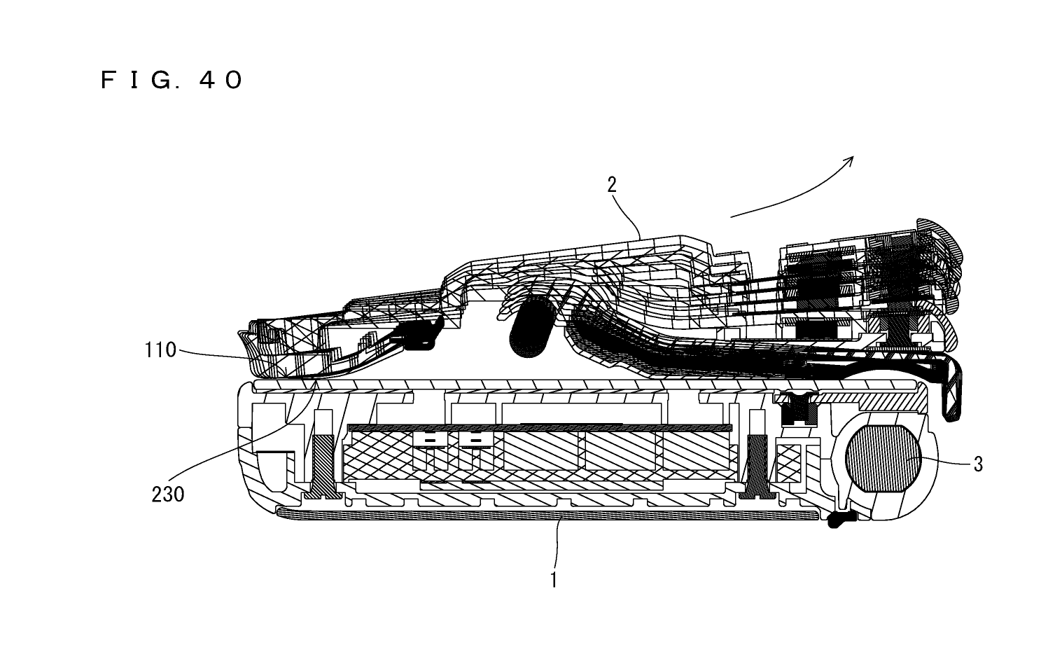

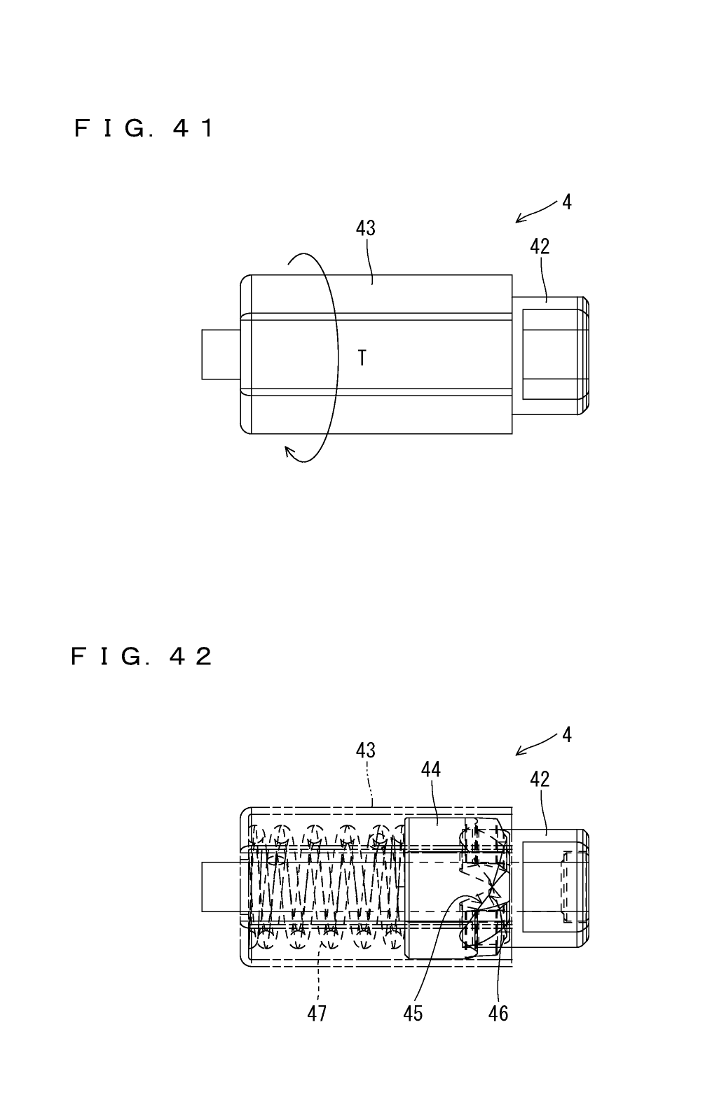

The relief surface 230 is formed in a belt-shape region that extends to left and right directions over a whole width of the back surface 231 of the second casing 2 as illustrated by hatching in FIG. 38.

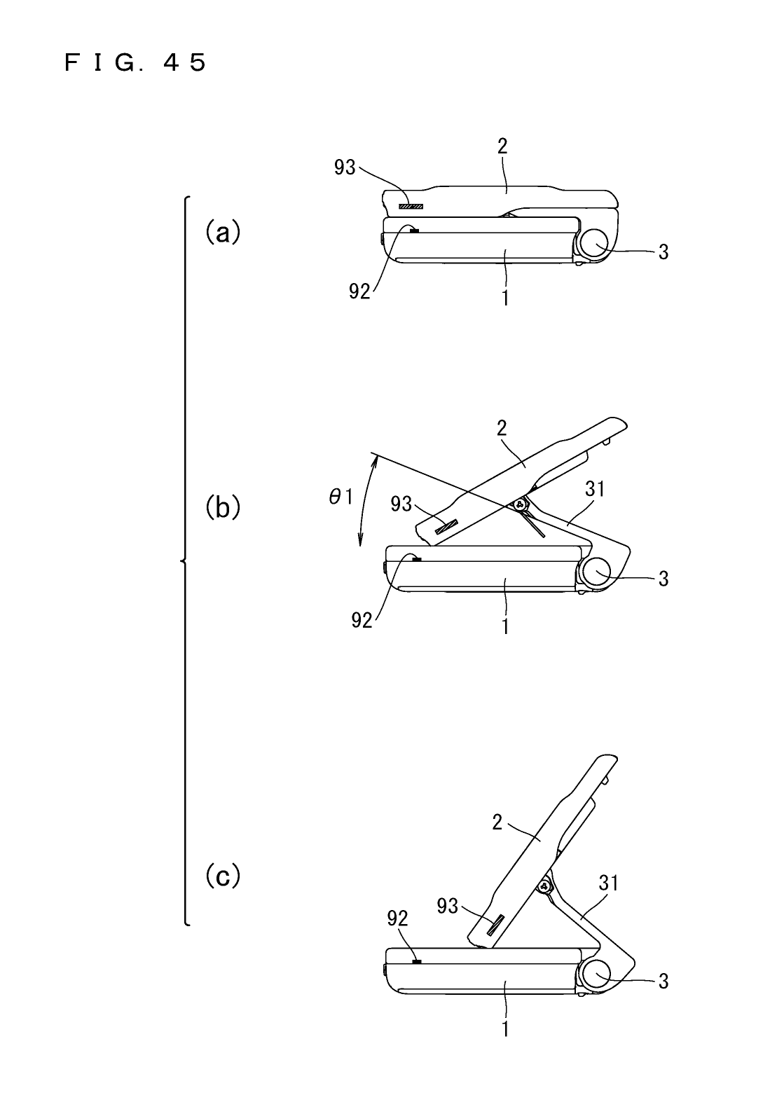

As illustrated in FIG. 7, a magnetic sensor 92 is incorporated in a right front end portion in the first casing 1, and a magnet 93 is incorporated in a right front end portion in the second casing 2. As illustrated in FIG. 45(a), in a closed state, the magnetic sensor 92 in the first casing 1 and the magnet 93 in the second casing 2 face each other and are close to each other.

In the closed state in FIG. 45(a), the magnetic sensor 92 becomes on by strongly receiving a magnetism from the magnet 93. When the coupling arm 31 reaches a predetermined turn angle θ1 (21°, for example) by a back-surface lower end portion of the second casing 2 sliding on the surface of the first casing 1 as illustrated in FIG. 45(b), the magnetic sensor 92 is separated from the magnet 93, and the magnetism from the magnet 93 becomes weak. As a result, the magnetic sensor 92 changes from on to off.

The magnetic sensor 92 maintains the off, in a state where the coupling arm 31 exceeds the predetermined turn angle θ1 as illustrated in FIG. 45(c).

Upon receiving on/off signals from the magnetic sensor 92, a control circuit (not illustrated) incorporated in the first casing 1 does not start an apparatus control in a tilt state, when the turn angle of the coupling arm 31 is smaller than the predetermined turn angle θ1 as illustrated in FIG. 45(a) to (b), and on the other hand, the control circuit starts an apparatus control in a tilt state, when the turn angle of the coupling arm 31 becomes equal to or larger than the predetermined turn angle θ1 as illustrated in FIG. 45(b) to (c).

When the cam curve of the second example illustrated in FIG. 44 is employed in the cam mechanism incorporated in the hinge unit 4, the predetermined turn angle θ1 is set slightly larger than the turn angle of the coupling arm 31 when both the casings 1, 2 are opened to an intermediate state between a closed state and a tilt state by grasping and raising only the second casing 2.

According to the portable electronic device, the apparatus can be selectively set in four states which include a closed state where the first casing 1 and the second casing 2 are laid over each other and only the second display surface 21 is exposed as illustrated in FIGS. 1 and 2, a tilt state where both the first display surface 11 and the second display surface 21 are exposed by moving the second casing 2 backward from the closed state and also the second display surface 21 is inclined to the first display surface 11 at an open angle equal to or larger than 90 degrees and smaller than 180 degrees as illustrated in FIGS. 3 and 4, a first open state where both the first display surface 11 and the second display surface 21 are exposed on the same plane by turning the second casing 2 backward from the tilt state as illustrated in FIGS. 5 and 6, and a second open state where the second casing 2 is slid to a first casing 1 side from the first open state, and the first display surface 11 and the second display surface 21 are exposed on the same plane at a position where both the display surfaces 11 and 12 are brought close to each other as illustrated in FIGS. 7 and 8.

In the closed state illustrated in FIGS. 1 and 2, the first arm portions 35, 35 of the coupling arms 31, 31 are accommodated in the accommodation portions 103, 103 of the first casing 1 illustrated in FIG. 10. At the same time, the arm coupling portion 37 of the coupling member 32 and the second arm portions 36, 36 are accommodated in the accommodation portions 204, 203, 203 of the second casing 2, and the apparatus as a whole is accommodated in compact, without involving a stretch of the coupling mechanism 3 from both side surface and back end surfaces of both the casings 1, 2.

Further, in a closed state, as illustrated in FIG. 18, the front end surface of the first casing 1 and the front end surface of the second casing 2 are aligned, and the projecting portions 200, 200 are stretched forward from the front end surfaces of both the casings 1, 2.

In any state of the tilt state illustrated in FIG. 3, the first open state illustrated in FIG. 5, and the second open state illustrated in FIG. 7, approximately a whole of the coupling mechanism 3 is hidden at back surface sides of both the casings 1, 2. A projection portion of the coupling mechanism 3 is not readily visible from a normal line of view of the user (the arrow S in FIG. 1).

In the second open state, the first arm portions 35, 35 of the coupling arms 31, 31 of the second casing 2 are accommodated, and at the same time, the projecting portions 200, 200 of the second casing 2 are accommodated, in the accommodation portions 103, 103 of the first casing 1 illustrated in FIG. 10.

As illustrated in FIG. 32(a) to (d) and in FIG. 33(a) to (d), in the process of shifting the portable electronic device from the closed state to the second open state via the tilt state and the first open state, when the second casing 2 is pressed backward and slightly moved in the closed state illustrated in FIG. 32(a), the second casing 2 thereafter turns to a counterclockwise direction indicated by an arrow of a broken line, based on a bias of the torsion spring 6, as illustrated in FIG. 32(b) to (d). Along this turn, the coupling arm 31 turns to a clockwise direction as indicated by an arrow of a solid line.

Accordingly, the second casing 2 moves backward by directing the second display surface 21 upward or with slightly inclined upward.

When the cam curve of the first example illustrated in FIG. 43 is employed in the cam mechanism incorporated in the hinge unit 4, both the casings 1, 2 are not opened from a closed state to a tilt state, by the own weight of the first casing 1, even when only the second casing 2 is grasped and raised.

To shift a state where both the casings 1, 2 are closed to a tilt state, a torque that exceeds the first torque value T1 is worked on the cam mechanism.

On the other hand, when the cam curve of the second example illustrated in FIG. 44 is employed in the cam mechanism incorporated in the hinge unit 4, both the casings 1, 2 are slightly opened to an intermediate state between a closed state and a tilt state, by the own weight of the first casing 1, when only the second casing 2 is grasped and raised. However, both the casings 1, 2 are not opened large to a tilt state.

To open both the casings 1, 2 from an open state to a tilt state, a torque that exceeds the second torque value T2 is worked on the cam mechanism. Therefore, pressing force necessary to press the second casing 2 backward in the closed state illustrated in FIG. 32(a) becomes small.

Further, even when both the casings 1, 2 are opened to an intermediate state (a cam state P1′) between a closed state and a tilt state by grasping and raising only the second casing 2, a turn angle of the coupling arm 31 at this time is smaller than the predetermined angle θ1 illustrated in FIG. 45(b). Therefore, the magnetic sensor 92 does not become off, and accordingly, an apparatus control in a tilt state, for example, a control of starting the first display, is not started.

Consequently, increase of power consumption due to unnecessary apparatus operation can be prevented.

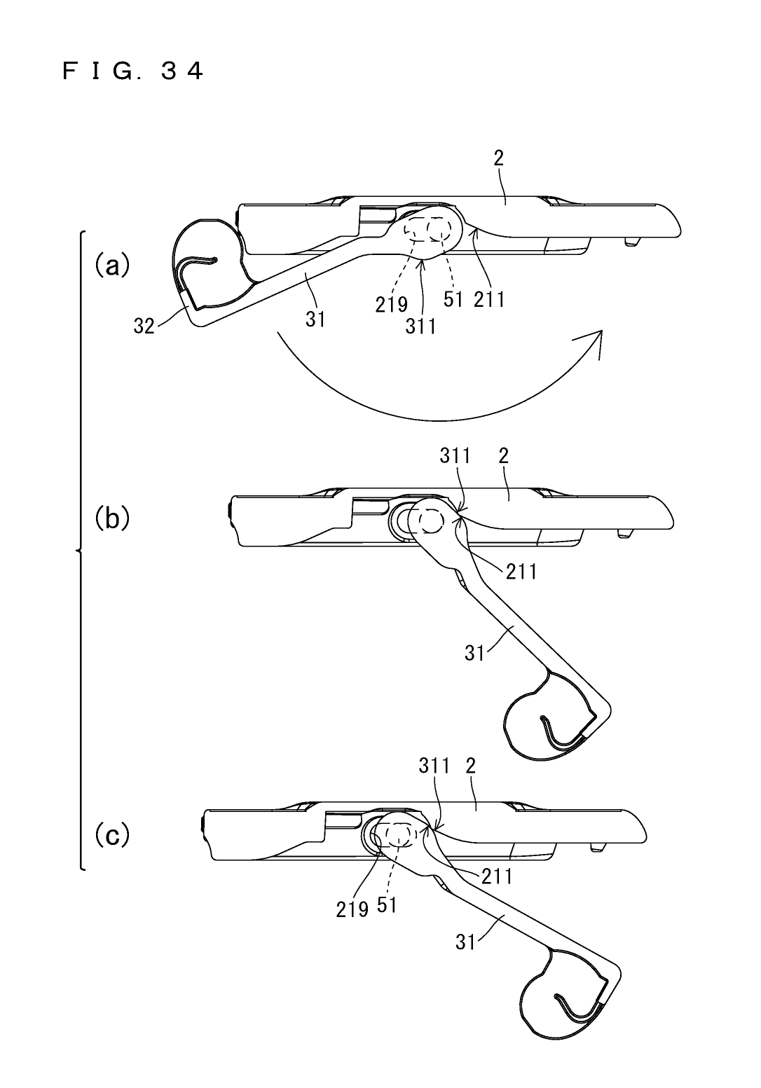

As described above, in the process of shifting from a closed state to a tilt state, the second casing 2 moves backward while gradually raising a posture from a horizontal posture to an inclined posture as illustrated in FIG. 34. In this process, a lower end portion (an end portion at a front side) of the back surface of the second casing 2 slides on the surface 110 of the first casing 1.

However, because the relief surface 230 is formed on the lower end portion of the back surface of the second casing 2, a contact pressure when the lower end portion of the back surface of the second casing 2 slides on the surface 110 of the first casing 1 becomes small, as compared with a contact pressure when the relief surface 230 like this is not formed.

Therefore, a damage that the surface 110 of the first casing 1 is likely to have at the time of shifting from a closed state to a tilt state can be reduced.

In the case of opening the second casing 2 from the closed state illustrated in FIG. 32(a), the second casing 2 can be also raised to an inclined posture, in a state of grasping the first casing 1 with one hand and sandwiching the casing 2 with the other hand by applying fingertips of the other hand to both side portions of the casing 2.

In this case, in the closed state, a front end portion (a portion which is coupled to the second casing) of the coupling arm 31 is covered with the first sidewall portion 212 of the sidewall 214 of the second casing 2 as illustrated in FIG. 32(a). Therefore, the fingertips of the hand that sandwich the second casing 2 are in contact with both the sidewalls 214, 214 of the second casing 2, and can securely sandwich the second casing 2, without feeling a pain in the fingertips.

Particularly, because the finger hang surface 215 is formed between the end surface of the first sidewall portion 212 and the end surface of the second sidewall portion 212, when the second casing 2 is sandwiched with the fingertips of the hand in the closed state, the fingertips can be applied to the fingertip hang surface 215, and accordingly, the second casing 2 can be raised securely.

Thereafter, at a time point slightly after the state in FIG. 32(d), the coupling arm 31 further turns to a clockwise direction as illustrated in FIG. 33(a) by the bias of the hinge unit 4, and is softly latched at a turn angle in the tilt state as illustrated in FIG. 33(b). Further, the second casing 2 turns to a counterclockwise direction by the bias of the torsion spring 6, and is held in a posture in the tilt state illustrated in FIG. 33(b), by the slide surface 29 being brought into contact with the receiving surface 33 of the coupling arm 31.

Therefore, when the user slightly moves the second casing 2 by pressing the casing 2 backward in the closed state illustrated in FIG. 32(a), the second casing 2 thereafter automatically moves to the tilt state illustrated in FIG. 33(b).

Next, when the coupling arm 31 is slightly turned to a clockwise direction by pressing the second casing 2 backward in the tilt state illustrated in FIG. 33(b), thereafter, the coupling arm 31 turns to the turn angle in the first open state illustrated in FIG. 33(c) by the bias of the hinge unit 4, by keeping the state where the slide surface 29 of the second casing 2 is in contact with the receiving surface 33 of the coupling arm 31, and the coupling arm 31 is received by the first casing 1 at this turn angle.

Along the turn of the coupling arm 31, the second casing 2 turns backward, and the first display surface 11 and the second display surface 21 are finally aligned on the same plane.

Further, when the second casing 2 is pulled to a first casing 1 side from the first open state illustrated in FIG. 33(c), as illustrated in FIG. 16(a) to (b), the second casing 2 comes close to the first casing 1 by keeping a horizontal posture, by the slide surface 29 of the second casing 2 sliding on the receiving surface 33 of the coupling arm 31.

At the same time, the recessed portion 20 of the second casing 2 comes close to the projecting portion 10 of the first casing 1 at a facing position.

In the process that the slide surface 29 of the second casing 2 slides on the receiving surface 33 of the coupling arm 31, the slide surface 29 is pressed against the receiving surface 33 by the bias force of the torsion spring 6. Accordingly, a horizontal posture of the second casing 2 is stabilized.

When the second casing 2 is further pulled to a first casing 1 side, as illustrated in FIG. 16(b) to (c), the slide surface 29 of the second casing 2 is separated from the receiving surface 33 of the coupling arm 31, and immediately after this, the projecting portion 10 of the first casing 1 and the recessed portion 20 of the second casing 2 start engaging with each other.

Finally, the recessed portion 20 of the second casing 2 is deeply engaged with the projecting portion 10 of the first casing 1 as illustrated in FIG. 16(c).

In this way, the second casing 2 horizontally moves to the second open state illustrated in FIG. 33(d), and is brought into contact with the first casing 1.

As a result, the first display surface 11 and the second display surface 21 come close to each other as illustrated in FIG. 7, and one large screen is formed by both the display surfaces 11 and 21.

In the second open state, with the engagement between the projecting portion 10 of the first casing 1 and the recessed portion 20 of the second casing 2 as illustrated in FIG. 16(c), both the casings 1, 2 are coupled to each other. Therefore, even when the second display surface 21 is strongly touched in this state, the second casing 2 is held in a constant posture to the first casing 1.

FIG. 17(a), (b), (c) express a state of a bent deformation of the flexible lead 7 in the process that the closed state reaches the second open state via the first open state.

In the closed state illustrated in FIG. 17(a), as described above, the slide contact surface 311 formed on the second arm portion 36 of the coupling arm 31 and the slide contact receiving surface 211 formed in the second casing 2 are brought into contact with each other, and the sliding of the second casing 2 to a direction indicated by an arrow of a two-dot chain line is inhibited.

In the first open state illustrated in FIG. 17(b), along the turn of the coupling arm 31, the flexible lead 7 is bent and deformed large between the second lead portion 72 and the third lead portion 73.

By sliding the second casing 2 forward (leftward in the drawing) by a distance T as indicated by an arrow in the drawing, the state illustrated in FIG. 17(b) reaches the second open state illustrated in FIG. 17(c). In this process, the flexible lead 7 is displaced forward with a further large curvature between the second lead portion 72 and the third lead portion 73.

According to the portable electronic device, because a movement of the second casing 2 to the direction indicated by the arrow of the chain line is inhibited in the closed state illustrated in FIG. 17(a), when the second casing 2 slides by an operation of the sliding mechanism 8, a length of the flexible lead 7 can be shortened by a marginal length that is given to the flexible lead 7.

Therefore, the flexible lead 7 can be formed in a length which takes into account the bent deformation of the flexible lead 7 following the turn of the coupling arm 31 illustrated in FIG. 17(a) to (c). Accordingly, a loose of the flexible lead 7 in the closed state illustrated in FIG. 17(a) can be restricted to a minimum necessary.

According to the portable electronic device, as illustrated in FIG. 23, the engaging piece 216 is provided in protrusion integrally with the front surface cabinet 2a made of a synthetic resin, and at the same time, the engagement receiving piece 222 is provided in protrusion integrally with the holder member 221 made of stainless steel. Therefore, the engaging piece 216 made of a synthetic resin and the engagement receiving piece 222 made of stainless steel can be engaged with each other.

A hook structure including the engaging piece made of a synthetic resin and the engagement receiving piece made of stainless steel is also employed to latch the first display 12 in the first casing 1 (not illustrated).

Therefore, as compared with a conventional configuration in which both the engaging piece and the engagement receiving piece are made of a synthetic resin, a gap between the first display 12 and the second display 22 in the open state becomes small by a reduction of a plate thickness following a change from the engagement receiving piece made of a synthetic resin to the engagement receiving piece made of stainless steel (about 1.0 mm as a total of both a first casing side and a second casing side in the above example).

Further, as described above, the first display 12 and the second display 22 are close to each other by being pressed by the elastic pieces 143, 243, and a gap between the displays 12 and 22 is minimized.

Therefore, when a large image is displayed by using both the display surfaces 11 and 22 as one screen in the state (the second open state) where the two display surfaces 11, 12 are aligned on the same plane as illustrated in FIG. 7, a satisfactory image display with a minor discontinuity can be realized.

In the portable electronic device, the first casing 1 and the second casing 2 can be directly shifted from the second open state to the tilt state without via the first open state, by applying turning force toward the tilt state to the second casing 2 in the second open state.

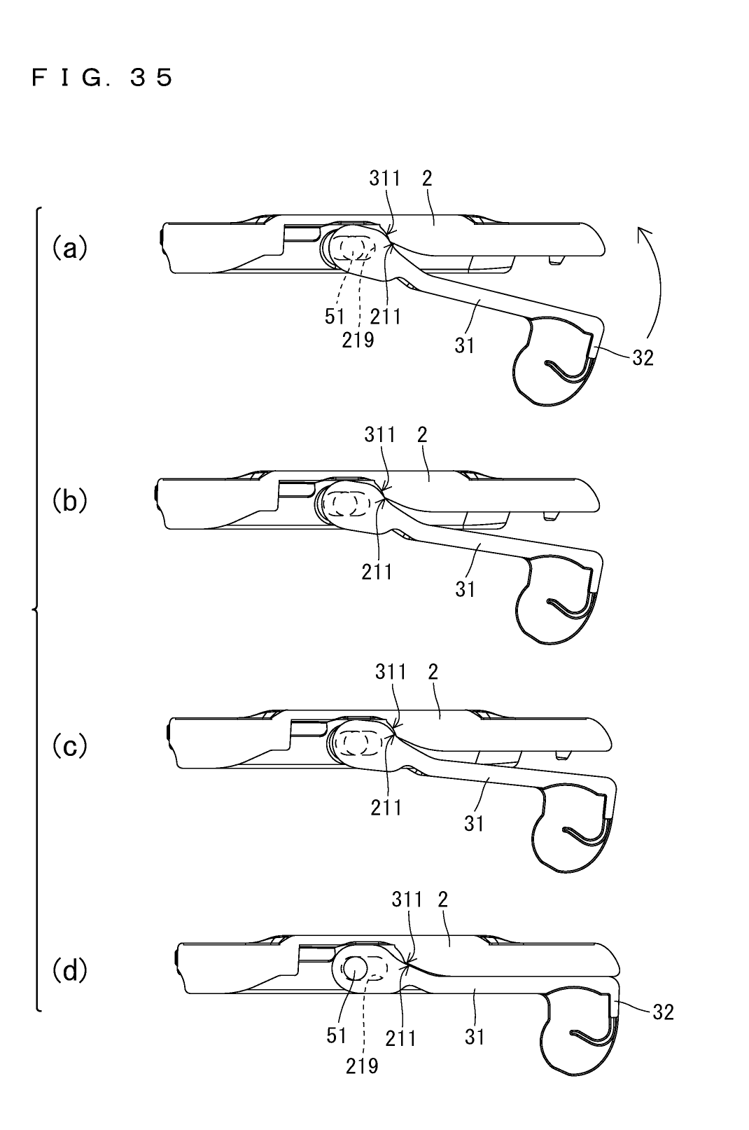

FIGS. 34 and 35 express a state where the slide contact surface 311 of the coupling arm 31 slides to the slide contact receiving surface 211 of the second casing 2, based on the second casing 2, in the process of reaching the closed state from the second open state via the tilt state.

In the second open state, the slide contact surface 311 of the coupling arm 31 and the slide contact receiving surface 211 of the second casing 2 are separated from each other as illustrated in FIG. 34(a). When the coupling arm 31 turns from this state as indicated by an arrow, the slide contact surface 311 of the coupling arm 31 becomes in slide contact with the slide contact receiving surface 211 of the second casing 2 as illustrated in FIG. 34(b).

Thereafter, when the coupling arm 31 turns to a closed state illustrated in FIG. 35(d), the slide contact surface 311 of the coupling arm 31 slides to the slide contact receiving surface 211 of the second casing 2 as illustrated in FIG. 34(b), (c) and FIG. 35(a) to (d). By the cam function following this slide, the axes (the hinge members 5, 51) at the second casing 2 side of the coupling arm 31 perform a relative movement to the second casing 2 in a slide direction (a left direction in the drawing) of the sliding mechanism.

In the closed state illustrated in FIG. 35(d), the axes (the hinge members 5, 51) at the second casing 2 side of the coupling arm 31 reach a slide moving end, by keeping a state where the slide contact surface 311 of the coupling arm 31 is in slide contact with the slide contact receiving surface 211 of the second casing 2.

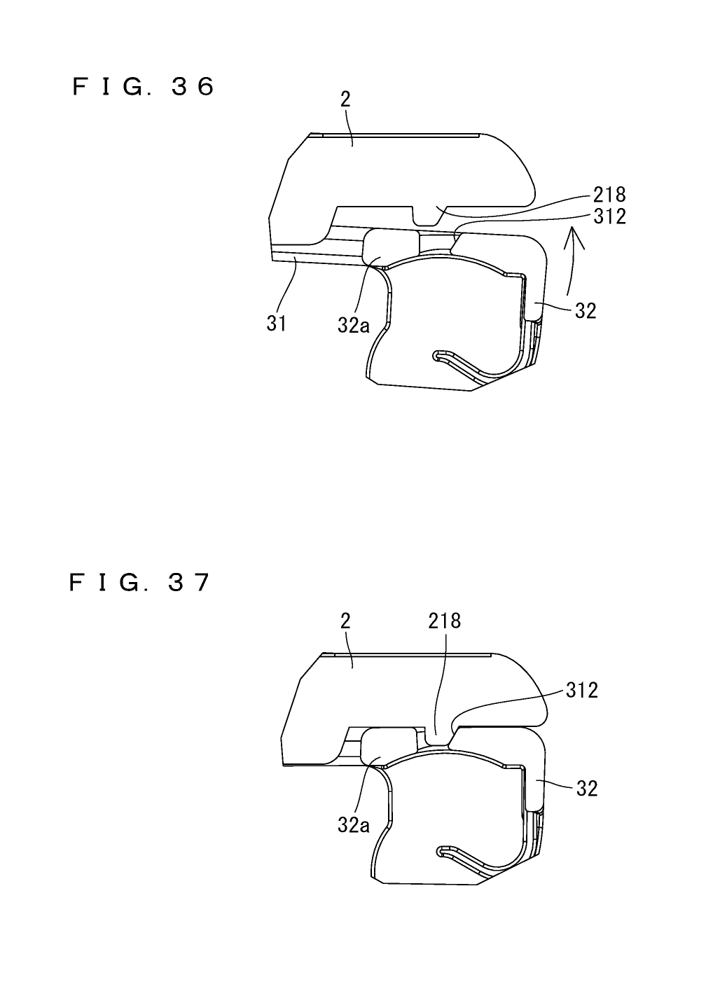

As described above, in the process of reaching the closed state from the second open state via the tilt state, by the slide contact surface 311 of the coupling arm 31 sliding to the slide contact receiving surface 211 of the second casing 2, the second casing 2 performs a relative movement to the coupling member 32 in a slide direction (a right direction in the drawing) of the sliding mechanism. At a final stage illustrated in FIG. 35(c) to (d), as illustrated in FIGS. 36 and 37, the projecting portion 218 of the second casing 2 enters the through-hole 312 of the coupling member 32, and the projecting portion 218 of the second casing 2 is engaged with the through-hole 312 of the coupling member 32.

In the state where the projecting portion 218 of the second casing 2 is engaged with the through-hole 312 of the coupling member 32, the slide contact surface 311 of the coupling arm 31 and the slide contact receiving surface 211 of the second casing 2 maintain the state of being in slide contact with each other, or the slide contact surface 311 of the coupling arm 31 is slightly separated from the slide contact receiving surface 211 of the second casing 2.

Therefore, in the closed state, when the slide contact receiving surface 211 of the second casing 2 is brought into contact with or faces the slide contact surface 311 of the coupling arm 31 as illustrated in FIG. 35(d), a movement of the second casing 2 forward (a left direction in the drawing) is inhibited. At the same time, when the back end surface of the projecting portion 218 of the second casing 2 is brought into contact with the internal peripheral surface at the back side of the through-hole 312 of the coupling member 32 as illustrated in FIG. 37, a backward movement of the second casing 2 (a right direction in the drawing) is inhibited.

In this way, a position of the second casing 2 relative to the first casing 1 in the closed state is constrained to a constant position or within a constant range, and the position of the second casing 2 is fixed.

As described above, according to the portable electronic device, even when an operation of shifting the second casing 2 from the second open state to the closed state without via the first open state is performed by applying turning force for the tilt state to the second casing 2 in the second open state, in the closed state, the projecting portion 218 of the second casing 2 can be engaged with the through-hole 312 of the coupling member 32, by moving the second casing 2 to a predetermined position relative to the first casing 1.

In the above example, the projecting portion 218 is provided in the second casing 2, and the through-hole 312 that becomes the recessed portion is provided in the coupling member 32. However, the provision is not limited to the above, and a recessed portion can be provided in the second casing 2, and a projecting portion can be provided in the coupling member 32, for example. Further, a structure is not limited to the recessed portion and the projecting portion, and it is sufficient that the structure is an engagement structure capable of inhibiting the slide of the second casing in the closed state.

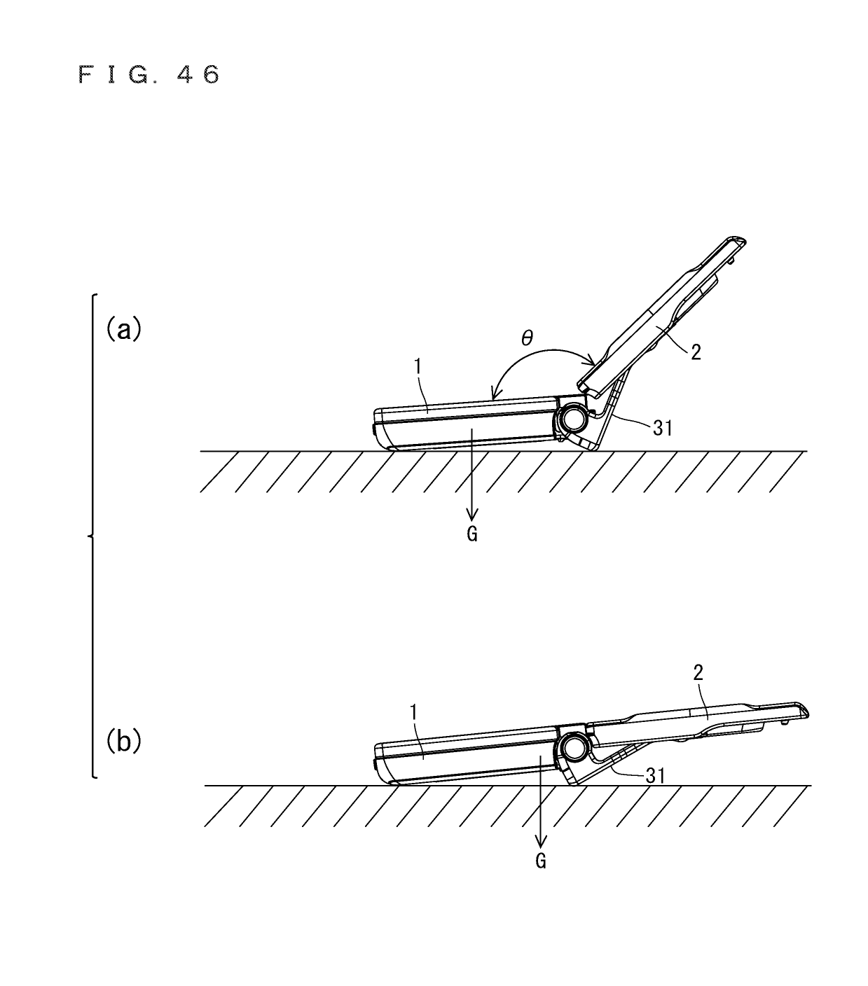

According to the portable electronic device, when the apparatus is placed on a desk in the tilt state as illustrated in FIG. 46(a) or is placed on the desk in the second open state as illustrated in FIG. 46(b), the corner portion of the coupling arm 31 is stretched from the back surface of the first casing 1, so that the front end portion of the first casing 1 and the corner portion of the coupling arm 31 are grounded.

In this case, layout of parts in the first casing 1 and the second casing 2 and the L-shape of the coupling arm 31 are designed such that a gravity center G comes to a first casing 1 side from the ground point of the coupling arm 31 in any state, as illustrated in the drawing. With this arrangement, posture of both the casings 1, 2 can be stabilized.

Therefore, when the portable electronic device is placed on the desk in the tilt state as illustrated in FIG. 46(a), the user can operate the touch panel of the first casing 1 at the front while watching the display of the second casing 2 at the back side, for example.

When the portable electronic device is placed on the desk in the second open state as illustrated in FIG. 46(b), both the display surfaces 11 and 21 become in a posture of being slightly inclined to a user side according to a projected amount of the corner portion of the coupling arm 31. Both the display surfaces 11 and 21 form one screen, for example, and the user can view an image by a large screen. In this case, because both the display surfaces 11 and 21 are in sufficiently close contact with each other, an image having substantially no discontinuity can be displayed on both the display surfaces 11 and 21.

Further, according to the portable electronic device, when the apparatus is dropped on a floor surface, and also when the apparatus takes a drop posture where the front end surface of the second casing 2 faces downward, any one projecting portion 200 out of the pair of projecting portions 200, 200 formed on the front end surface first collides with the floor surface, and immediately after this, the other projecting portion 200 collides with the floor surface.

In this case, as illustrated in FIG. 20, the second display 22 is arranged as close as possible to the front end surface of the second casing 2, and the glass plate 24 is arranged by covering the second display 22. Therefore, a distance between the front end surface of the glass plate 24 and the front end surface of the second casing 2 is very small. When impulsive force works on the front end surface of the second casing 2, for example, the impulsive force reaches the glass plate 24, and this has a risk of breaking the glass plate 24.

However, according to the portable electronic device, the pair of projecting portions 200, 200 are arranged at positions deviated from the glass plate 24 of the second casing 2, and also at the position deviated from the second display 22 to a width direction. Because the projecting portion 200 exhibits a buffer effect corresponding to the height of the projecting portion 200, the impulsive force that works on the glass plate 24 covering the second display 22 and on the second display 22 is substantially alleviated as compared with impulsive force that works when the front end surface not formed with the projecting portion 200 collides with the floor surface.

As a result, breakage of the glass plate 24 and the second display 22 due to the work of the impulsive force is reduced.

Impulsive force due to a drop similarly works on the glass plate 16 of the first casing 1. However, in the closed state, because the back end surface of the first casing 1 is covered with the coupling member 32 illustrated in FIG. 9, the impulsive force to the glass plate 16 of the first casing 1 can be alleviated.

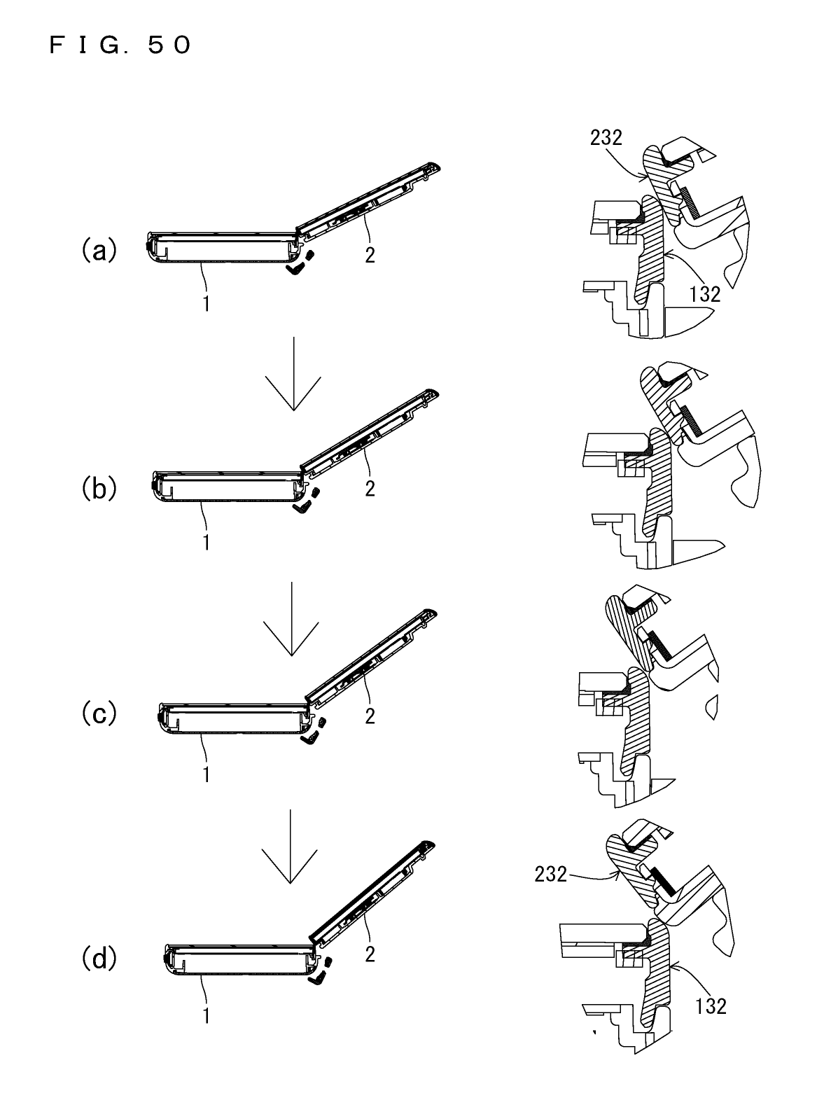

Further, according to the portable electronic device, when only turning force is applied to the second casing 2 in the second open state illustrated in FIG. 48(a), the apparatus can be directly shifted from this state to the tilt state illustrated in FIG. 50(d) without via the first open state.

That is, in the second open state illustrated in FIG. 48(a), the first engagement surface 10a of the projecting portion 10 and the first engagement receiving surface 20a of the recessed portion 20 are brought into contact with each other, and the second casing 2 is received with this contact. However, a slight gap is formed between the third engagement surface 10c of the projecting portion 10 and the third engagement receiving surface 20c of the recessed portion 20.

When turning force in a rise direction is applied to the second casing 2 in this state, as illustrated in FIG. 48(b), the end surface 132 of the first casing 1 and the end surface 232 of the second casing 2 are brought into contact with each other, and a turning torque around this contact portion works on the second casing 2.

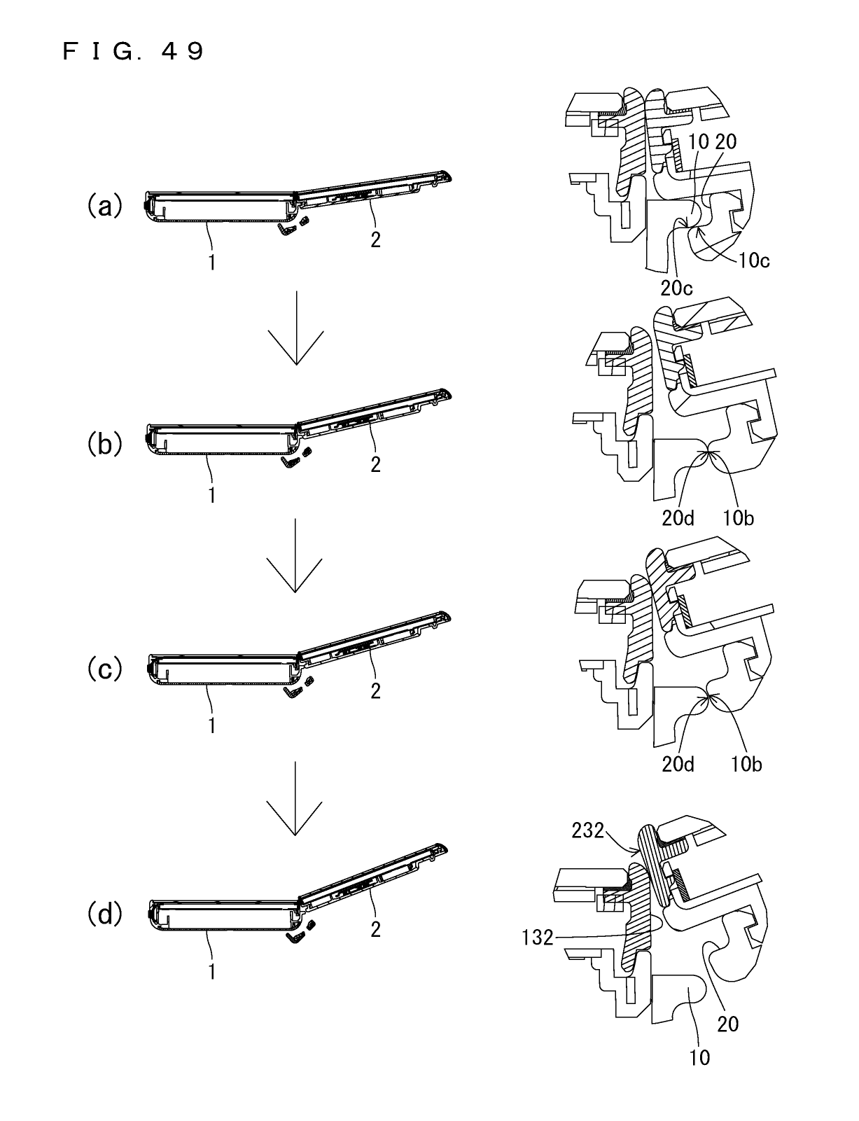

As a result, the second casing 2 turns around the contact portion, and the first engagement receiving surface 20a of the recessed portion 20 slides on the first engagement surface 10a of the projecting portion 10 following this turning. Accordingly, the second casing 2 slightly recedes and is also inclined. With a further turning of the second casing 2 around the contact portion, the engagement between the projecting portion 10 and the recessed portion 20 becomes shallow as illustrated in FIG. 49(a), and the third engagement receiving surface 20c of the recessed portion 20 becomes in slide contact with the third engagement surface 10c of the projecting portion 10.

When turning force is further applied to the second casing 2, the fourth engagement receiving surface 20d of the recessed portion 20 slides along the second engagement surface 10b of the projecting portion 10 as illustrated in FIG. 49(b). By the cam operation following this, the second casing 2 is pushed out in a direction separated from the first casing 1.

When turning force is further applied to the second casing 2, the fourth engagement receiving surface 20d of the recessed portion 20 further slides along the second engagement surface 10b of the projecting portion 10 as illustrated in FIG. 49(c). As illustrated in FIG. 49(d), the recessed portion 20 is completely detached from the projecting portion 10.

As described above, when turning force is applied to the second casing 2 in the second open state illustrated in FIG. 48(a), in the process that the recessed portion 20 is detached from the projecting portion 10, a movement in a horizontal direction of being separated from the first casing 1 and a turning toward an inclined posture in the tilt state simultaneously proceed in the second casing 2.

When the second casing 2 further turns as illustrated in FIGS. 50(a), (b), (c), the end surface 232 of the second casing 2 slides along the end surface 132 of the first casing 1, and finally shifts to the tilt state as illustrated in FIG. 50(d).

In a latter half of the process that the second casing 2 shifts from the second open state to the tilt state, because bias force toward the tilt state works on the second casing 2 by the cam operation of the hinge unit (4), the second casing 2 automatically shifts to the tilt state.

In this way, with the engagement relationship between the engagement surfaces 10a, 10b, 10c and the engagement receiving surfaces 20a, 20b, 20c, 20d that are formed on the projecting portion 10 and the recessed portion 20, respectively, in the second open state illustrated in FIG. 48(a), upper and lower relative movements that are orthogonal to the slide directions of both the casings 1, 2 are constrained, and at the same time, in the shift process to the tilt state illustrated in FIG. 48(b) to FIG. 50(d), displacement of turning the second casing 2 to the inclined posture in the tilt state while separating both the casings 1, 2 from each other is allowed.

According to the portable electronic device, at the time of shifting the apparatus from the second open state to the tilt state, the user can directly shift the apparatus from the open state to the tilt state, by simply applying turning force to the second casing 2 without performing an operation of separating the second casing 2 from the first casing 1. Therefore, the operation for setting the tilt state from the second open state becomes simple.

### DESCRIPTION OF REFERENCE CHARACTERS

(1) First casing
(10) Projecting portion
(10a) First engagement surface
(10b) Second engagement surface
(10c) Third engagement surface
(11) First display surface
(12) First display
(16) Glass plate
(110) Surface
(124) Accommodation chamber
(125) Internal peripheral surface
(143) Elastic piece
(2) Second casing
(20) Recessed portion
(20a) First engagement receiving surface
(20b) Second engagement receiving surface
(20c) Third engagement receiving surface
(20d) Fourth engagement receiving surface
(21) Second display surface
(22) Second display
(29) Slide surface
(24) Glass plate
(211) Slide contact receiving surface
(200) Projecting portion
(214) Sidewall
(215) Finger hang surface
(216) Engaging piece
(218) Projecting portion
(221) Holder member
(222) Engagement receiving surface
(223) Hole
(230) Relief surface
(231) Back surface
(224) Accommodation chamber
(225) Internal peripheral wall
(243) Elastic piece
(3) Coupling mechanism
(31) Coupling arm
(35) First arm portion
(36) Second arm portion
(33) Receiving surface
(311) Slide contact surface
(312) Through-hole
(4) Hinge unit
(42) Fixed cam piece
(43) Movable cam piece
(47) Spring
(5) Hinge member
(6) Torsion spring
(7) Flexible lead
(8) Sliding mechanism
(83) Sliding member
(92) Magnetic sensor
(93) Magnet

1. A portable electronic device that has a first casing and a second casing coupled to each other via a coupling member, and is selectively set in at least two states which include a closed state where a surface of the first casing is covered with a back surface of the second casing and a surface of the second casing is exposed, and an open state where the second casing moves from the closed state by a turn operation of the coupling mechanism and the surface of both the casings are exposed on the same plane, wherein
a supporting mechanism that turnably and slidably supports the second casing relative to a front end portion of the coupling member is interposed between the front end portion of the coupling member and the second casing, and the first casing and the second casing are brought close to each other and separated from each other in the open state, and
at an opposing portion between the coupling member and the second casing, there are formed a receiving surface and a slide surface that are to be in slide contact with each other in a first half of a process in which both the casings shift from a most separated state to a closest state in the open state, and at an opposing portion between the first casing and the second casing, there are formed a projecting portion and a recessed portion that are to be detachably engaged with each other in a latter half of the process.

2. The portable electronic device according to claim 1, wherein between the coupling member and the second casing, a spring is interposed which turnably biases the second casing to a direction in which the receiving surface and the slide surface are brought into a pressure contact with each other.

3. The portable electronic device according to claim 1, wherein in the process in which both the casings shift from a most separated state to a closest state in the open state, the projecting portion and the recessed portion start engaging with each other at the same time as when, or immediately before or immediately after the receiving surface and the slide surface are separated from each other.

4. A portable electronic device that has a first casing and a second casing coupled to each other and is selectively set in three states which include a closed state where a surface of the first casing is covered with a back surface of the second casing and a surface of the second casing is exposed, a tilt state where the surface of the second casing is inclined with respect to the surface of the first casing at an open angle equal to or larger than 90 degrees and smaller than 180 degrees and the surfaces of both the casings are exposed, and an open state where the surfaces of both the casings are exposed on the same plane, wherein,
the first casing and the second casing include a projecting portion and a recessed portion that are engaged with and disengaged from each other by being brought close to each other and separated from each other in the open state, and the projecting portion and the recessed portion are formed with an engagement surface and an engagement receiving surface that constrain a relative movement of both the casings in a direction orthogonal to a direction of being brought close to each other and separated from each other in a mutually engaged state, and allow displacement of turning the second casing from the open state to an inclined posture in the tilt state while separating both the casings from each other.

5. The portable electronic device according to claim 4, wherein the first casing and the second casing have end surfaces that face each other in the open state, the projecting portion is provided on the end surface of one of the casings, and the recessed portion is provided on the end surface of the other casing.

6. The portable electronic device according to claim 4, wherein the first casing and the second casing are coupled to each other via a coupling member, a supporting mechanism that turnably and slidably supports the second casing relative to a front end portion of the coupling member is interposed between the front end portion of the coupling member and the second casing, and the first casing and the second casing are brought close to each other and separated from each other in the open state.

7. The portable electronic device according to claim 4, wherein the coupling member includes a pair of left and right coupling arms arranged at both side portions of the first casing and the second casing, and the coupling arm has its one end portion coupled to the first casing by a first axis and has the other end portion coupled to the second casing by a second axis parallel with the first axis.

8. A portable electronic device that has a first casing and a second casing coupled to each other, a display arranged in each of the casings, and a display surface formed to be exposed on a surface of each of the casings, the portable electronic device being selectively set in at least two states which include a closed state where a display surface of the first casing is covered with a back surface of the second casing and a display surface of the second casing is exposed, and an open state where the display surfaces of both the casings are exposed on the same plane, wherein,
an accommodation chamber for accommodating a display is formed in at least one of the casings, and between an internal peripheral wall of the accommodation chamber and an external peripheral wall of the display accommodated in the accommodation chamber, there is arranged a pressing mechanism that presses the display to the other casing side in the open state.

9. The portable electronic device according to claim 8, wherein the display includes a display main body and a frame unit made of a synthetic resin that surrounds the display main body, a plurality of elastic pieces that are stretched toward an internal peripheral wall of the accommodation chamber which accommodates the display are formed on the frame unit, and the pressing mechanism is configured by the elastic pieces.

10. The portable electronic device according to claim 8, wherein the first casing and the second casing are coupled to each other via a coupling member, a supporting mechanism that turnably and slidably supports the second casing relative to an end portion of the coupling member is interposed between the end portion of the coupling member and the second casing, and the first casing and the second casing are brought close to each other and separated from each other in the open state.

11. The portable electronic device according to claim 8, wherein the coupling member includes a pair of left and right coupling arms arranged at both side portions of the first casing and the second casing, and the coupling arm has its one end portion coupled to the first casing by a first axis and has the other end portion coupled to the second casing by a second axis parallel with the first axis.
